(19) United States
(12) Patent Application Publication
(10) Pub. No.: US 2026/0065972 A1
(43) Pub. Date: Mar. 5, 2026

(54) TWO-STAGE MEMORY CELL PROGRAMMING

(71) Applicant: MICRON TECHNOLOGY, INC., Boise, ID (US)

(72) Inventors: Lawrence Celso Miranda, San Jose, CA (US); Sheyang Ning, San Jose, CA (US); Jeffrey S. McNeil, Boise, ID (US); Tomoko Ogura Iwasaki, San Jose, CA (US); Huai-Yuan Tseng, San Ramon, CA (US); Akira Goda, Tokyo (JP); Eric N. Lee, San Jose, CA (US); Koichi Kawai, Yokohama (JP); Yoshihiko Kamata, Yokohama-city (JP)

(21) Appl. No.: 19/308,518

(22) Filed: Aug. 25, 2025

Related U.S. Application Data
(60) Provisional application No. 63/687,925, filed on Aug. 28, 2024.

(51) Int. Cl. G11C 11/4094

(52) U.S. Cl. CPC G11C 11/4094

(57) ABSTRACT

Systems and methods for two-stage memory cell programming. An example memory device comprises: a memory array; and a controller coupled to the memory array, the controller to perform operations comprising: receiving a request to perform a memory programming operation with respect to a target set of memory cells electrically coupled to a target wordline and a set of target bitlines; performing a first stage of the memory programming operation by causing a ramping up programming voltage to be applied to the target wordline while causing one or more pillars associated with the target memory cells to be boosted in a staggered manner; and performing a second stage of the memory programming operation by causing a programming voltage to be applied to the target wordline, while selectively applying bias voltage to the set of target bitlines.

### REFERENCE TO RELATED APPLICATION

This application claims the priority benefit of U.S. Provisional Patent Application No. 63/687,925, filed Aug. 28, 2024, the entirety of which is incorporated herein by reference.

### TECHNICAL FIELD

Implementations of the disclosure relate generally to memory sub-systems, and more specifically, to two-stage memory cell programming.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various implementations of the disclosure.

FIG. 1A illustrates an example computing system that includes a memory sub-system in accordance with some implementations of the present disclosure.

FIG. 1B is a block diagram of a memory device in communication with a memory sub-system controller of a memory sub-system, according to an implementation.

FIG. 2A schematically illustrates a set of memory cells as arranged in a memory device.

FIG. 2B schematically illustrates schematically dependence of the source-drain current on the control gate voltage for two memory cells.

FIG. 2C schematically illustrates an example distribution of threshold control gate voltages for a memory cell.

FIG. 3A schematically illustrates a three-dimensional structure of an example memory cell string of a memory device operating in accordance with implementations of the present disclosure.

FIG. 3B illustrates an example set of pillars of an example memory array operating in accordance with implementations of the present disclosure

FIG. 4 schematically illustrates a high-level overview of a two-stage programming operation implemented in accordance with implementations of the present disclosure.

FIG. 5 illustrates example voltage waveforms of various portions of a memory array during execution of an ALP programming operation in accordance with implementations of the present disclosure.

FIG. 6 illustrates an example ALP programming operation including a set of multiple pulses applied to program all programming levels of a specified set of memory cells in accordance with implementations of the present disclosure.

FIG. 7 is a flow diagram of an example method of performing an all-level programming (ALP) operation, in accordance with implementations of the present disclosure.

FIG. 8 schematically illustrates the selective slow program convergence (SSPC) technique, in accordance with implementations of the present disclosure.

FIG. 9 is a flow diagram of an example method of performing an SSPC memory programming operation, in accordance with implementations of the present disclosure.

FIG. 10A is a graph illustrating a program distribution for a number of memory cells intended to be programmed to a given program level (i.e., state) by an analog selective slow program convergence (ASSPC) programming operation in accordance with implementations of the present disclosure.

FIG. 10B is a graph illustrating the data line bias voltages applied to different memory cells during by an ASSPC programming operation in accordance with implementations of the present disclosure.

FIG. 11 is a flow diagram of an example method of performing an ASSPC memory programming operation, in accordance with implementations of the present disclosure.

FIG. 12 is a diagram illustrating various signals applied to various components of a memory device by an ASSPC programming operation in accordance with implementations of the present disclosure.

FIG. 13 is a flow diagram of another example method of performing a two-stage memory programming operation, in accordance with implementations of the present disclosure.

FIG. 14 is a block diagram of an example computer system in which implementations of the present disclosure can operate.

### DETAILED DESCRIPTION

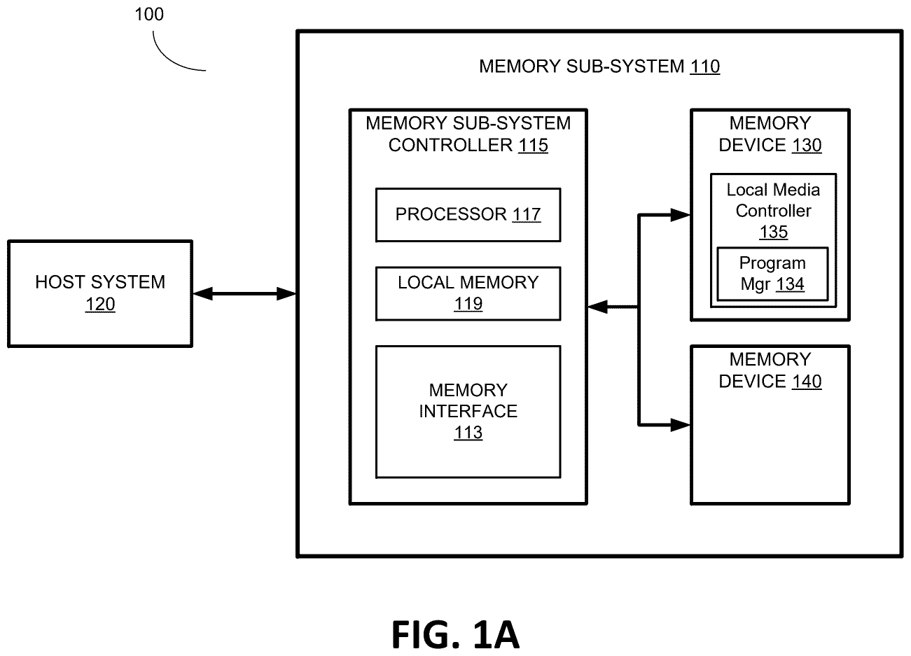

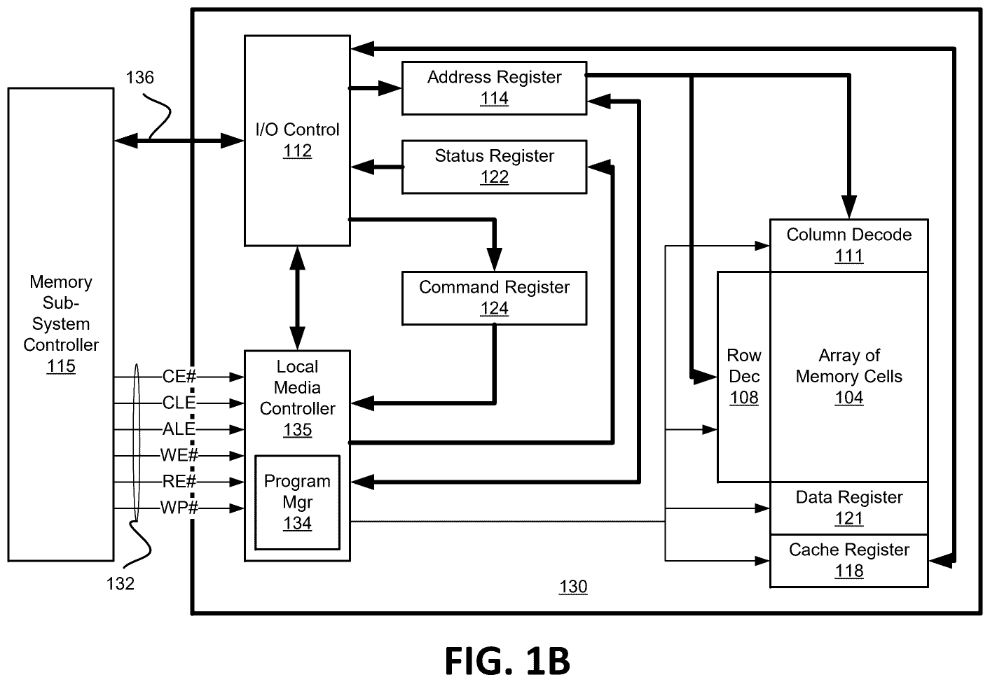

Aspects of the present disclosure are directed to two-stage memory cell programming. One or more memory devices can be a part of a memory sub-system, which can be a storage device, a memory module, or a hybrid of a storage device and memory module. Examples of storage devices and memory modules are described below in conjunction with FIGS. 1A-1B. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a negative-and (NAND) memory device. Other examples of non-volatile memory devices are described below in conjunction with FIGS. 1A-1B. A non-volatile memory device is a package of one or more dies. Each die can include of one or more planes. For some types of non-volatile memory devices (e.g., NAND devices), each plane includes of a set of physical blocks. In some implementations, each block can include multiple sub-blocks. Each sub-block includes a set of memory cells (“cells”). A memory cell is an electronic circuit that stores information. Depending on the cell type, a memory cell can store one or more bits of information, and its charge level can define various logic states that correlate to the number of bits being stored. The logic states can be represented by binary values, such as “0” and “1”, or combinations of such values. Each block and sub-block can be selectively accessed by memory access operations (e.g., read, write, erase operations).

A memory device (e.g., a memory die) can include memory cells arranged in a two-dimensional or a three-dimensional grid. The memory cells are formed onto a silicon wafer in an array of columns and rows. The memory cells are joined by wordlines, which are conducting lines electrically connected to the control gates of the memory cells, and bitlines, which are conducting lines electrically connected to the drain electrodes of the memory cells. The intersection of a bitline and wordline constitutes the address of the memory cell.

“Block” refers to a unit of the memory device used to store data and can include a group of memory cells, a word line group, a word line, or individual memory cells. Each block can include a number of sub-blocks, where each sub-block is defined by an associated pillar (e.g., a vertical conductive trace) extending from a shared bitline. Memory pages (also referred to herein as “pages”) store one or more bits of binary data corresponding to data received from the host system. To achieve high density, a string of memory cells in a non-volatile memory device can be constructed to include a number of memory cells at least partially surrounding a pillar of a poly-silicon channel material (i.e., a channel region). The memory cells can be coupled to access lines (i.e., wordlines) so as to form an array of strings in a block of memory (e.g., a memory array). The compact nature of certain non-volatile memory devices, such as 3D flash NAND memory, means that word lines are common to many memory cells within a block of memory. Some memory devices use certain types of memory cells, such as triple-level cell (TLC) or quadruple level cell (QLC), which store three bits of data in each memory cell, which make it affordable to move more applications from legacy hard disk drives to newer memory sub-systems, such as NAND solid-state drives (SSDs).

A memory write (programming) operation can be performed with respect to a target subset of memory cells of a memory device by sequentially applying programming voltage pulses to selected wordlines, which are connected to the target subset of memory cells. In some implementations, the programming pulse voltage can be sequentially ramped up from the initial voltage value (e.g., 0V) to the final voltage value (e.g., V_{PGM MAX}). Accordingly, a memory cell programming operation can involve applying series of incrementing voltage programming pulses to the target subset of memory cells in order to gradually increase their charge level.

Various operational and data reliability requirements determine various parameters of the threshold voltage distributions of programmed memory cells, such as the distribution width (e.g., the difference between the maximum and minimum threshold voltage of a group of memory cells that have been programmed to the same logical level). In order to produce threshold voltage distributions that satisfy the derided parameters, higher numbers of programming voltage pulses can be needed, thus adversely affecting the timing and other efficiency characteristics of memory programming operations.

Systems and methods of the present disclosure alleviate the above-noted and other deficiencies, by performing programming operations in two stages, such that each stage involves one or more programming pulses followed by respective verification operations.

Stage one of the programming operation utilizes the all-level programming (ALP) technique, which places, for each logical level (e.g., L1-L7 for triple-level cell (TLC), as illustrated), the corresponding threshold voltage distribution of the target memory cells to the vicinity of the desired position defined by the corresponding program verify voltage level(s). In some implementations, the desired position of the center of a threshold voltage distribution for a given logical level (L1-L7) matches the program verify voltage for that logical level. The desired position of the center of a threshold voltage distribution for a given logical level can matches the corresponding program verify voltage PV for that logical level.

In some implementations, stage one of the programming operation simultaneously programs the target memory cells at multiple logical levels by boosting the pillars in a staggered manner, while ramping up the voltage applied to the unselected wordlines to the pass voltage level and the voltage applied to the selected wordlines to the programming voltage level, as described in more detail herein below.

Stage one of the programming operation can further involve classifying the memory cells by their respective positions in the resulting threshold voltage distributions, which can be done based on the results of the program verify operations performed after the programming pulse(s) of stage one of the programming operation.

In some implementations, the memory cells of a threshold voltage distribution for a given logical level can be classified into a pre-defined number of sections based on the program verify voltages and pre-program verify voltages of that logical level and the previous logical level.

Stage two of the programming operation compacts the threshold voltage distributions in order to achieve the desired distribution parameters (e.g., the distribution width). In some implementations, stage two employ the selective slow program convergence (SSPC) technique, which can utilize the results of the above-described memory cell classification in order to assign, to each memory cell or group of memory cells, a corresponding bitline bias for seeding the pillar during stage two of the programming operation, which is intended to compact the threshold voltage distributions in order to achieve the desired distribution parameters (e.g., distribution width), as described in more detail herein below.

Alternatively, stage two of the programming operation can employ the analog selective slow program convergence (ASSPC) technique, which, instead of using a uniform bitline voltage, uses an analog or continuous voltage applied to the bitline (“analog bitline voltage level” or “continuous bitline voltage level”). Thus, the bitline voltage is biased continuously starting from the time of the threshold voltage of the associated memory cells reaching a corresponding pre-program verify threshold voltage until the bitline voltage reaches the fixed value at the time of threshold voltage of the associated memory cell reaching a program verify threshold voltage, as described in more detail herein below.

FIG. 1A illustrates an example computing system 100 that includes a memory sub-system 110 in accordance with some implementations of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some implementations, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include negative-and (NAND) type flash memory and write-in-place memory, such as a three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some implementations, each of the memory devices 130 can include one or more arrays of memory cells such as SLCs, MLCs, TLCs, QLCs, or any combination of such. In some implementations, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can be a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some implementations, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another implementation of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some implementations, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some implementations, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some implementations, memory sub-system 110 is a managed memory device, which includes a raw memory device 130 having control logic (e.g., local media controller 135) on the die and a controller (e.g., memory sub-system controller 115) for media management within the same memory device package. An example of a managed memory device is a managed NAND (MNAND) device.

In some implementations, the memory sub-system 110 includes a memory interface component 113. Memory interface component 113 is responsible for handling interactions of memory sub-system controller 115 with the memory devices of memory sub-system 110, such as memory device 130. For example, memory interface component 113 can send memory access commands corresponding to requests received from host system 120 to memory device 130, such as program commands, read commands, or other commands. In addition, memory interface component 113 can receive data from memory device 130, such as data retrieved in response to a read command or a confirmation that a program command was successfully performed. For example, the memory sub-system controller 115 can include a processor 117 (processing device) configured to execute instructions stored in local memory 119 for performing the operations described herein.

In some implementations, memory device 130 includes a program manager 134 configured to carry out corresponding memory access operations, in response to receiving the memory access commands from memory interface 113. In some implementations, local media controller 135 includes at least a portion of program manager 134 and is configured to perform the functionality described herein. In some implementations, program manager 134 is implemented on memory device 130 using firmware, hardware components, or a combination of the above. In some implementations, instructions implementing methods 800 and/or 900 described herein below can be stored as instructions (e.g., firmware) on memory device 130 and the program manager 134 can be implemented as control logic (e.g., local media controller 135) executing these instructions.

In some implementations, program manager 134 receives, from a requestor, such as memory interface 113, a request to program data to a memory array of memory device 130. The memory array can include an array of memory cells formed at the intersections of wordlines and bitlines. In some implementations, the memory cells are grouped in to blocks, which can be further divided into sub-blocks, where a given wordline is shared across a number of sub-blocks, for example. In some implementations, each sub-block corresponds to a separate plane in the memory array. The group of memory cells associated with a wordline within a sub-block is referred to as a physical page. In some implementations, there can be multiple portions of the memory array, such as a first portion where the sub-blocks are configured as SLC memory and a second portion where the sub-blocks are configured as multi-level cell (MLC) memory (i.e., including memory cells that can store two or more bits of information per cell). For example, the second portion of the memory array can be configured as TLC memory. The voltage levels of the memory cells in TLC memory form a set of 8 programming distributions representing the 8 different combinations of the three bits stored in each memory cell. Depending on how they are configured, each physical page in one of the sub-blocks can include multiple page types. For example, a physical page formed from single level cells (SLCs) has a single page type referred to as a lower logical page (LP). Multi-level cell (MLC) physical page types can include LPs and upper logical pages (UPs), TLC physical page types are LPs, UPs, and extra logical pages (XPs), and QLC physical page types are LPs, UPs, XPs and top logical pages (TPs). For example, a physical page formed from memory cells of the QLC memory type can have a total of four logical pages, where each logical page can store data distinct from the data stored in the other logical pages associated with that physical page.

In some implementations, program manager 134 can receive data to be programmed to the memory device 130 (e.g., a TLC memory device). Accordingly, program manager 134 can perform one or more programming operations to program each memory cell to a desired logical level (e.g., L1-L15 for QLC). In some implementations, program manager 134 performs each programming operation in two stages, such that each stage involves one or more programming pulses followed by respective verification operations.

Stage one of the programming operation utilizes the all-level programming (ALP) technique, which places, for each logical level (e.g., L1-L7 for triple-level cell (TLC), as illustrated), the corresponding threshold voltage distribution of the target memory cells to the vicinity of the desired position defined by the corresponding program verify voltage level(s). In some implementations, the desired position of the center of a threshold voltage distribution for a given logical level (L1-L7) matches the program verify voltage for that logical level. The desired position of the center of a threshold voltage distribution for a given logical level can matches the corresponding program verify voltage PV for that logical level.

In some implementations, stage one of the programming operation simultaneously programs the target memory cells at multiple logical levels by boosting the pillars in a staggered manner, while ramping up the voltage applied to the unselected wordlines to the pass voltage level and the voltage applied to the selected wordlines to the programming voltage level, as described in more detail herein below.

Stage one of the programming operation can further involve classifying the memory cells by their respective positions in the resulting threshold voltage distributions, which can be done based on the results of the program verify operations performed after the programming pulse(s) of stage one of the programming operation.

In some implementations, the memory cells of a threshold voltage distribution for a given logical level can be classified into a pre-defined number of sections based on the program verify voltages and pre-program verify voltages of that logical level and the previous logical level.

Stage two of the programming operation compacts the threshold voltage distributions in order to achieve the desired distribution parameters (e.g., the distribution width). In some implementations, stage two employ the selective slow program convergence (SSPC) technique, which can utilize the results of the above-described memory cell classification in order to assign, to each memory cell or group of memory cells, a corresponding bitline bias for seeding the pillar during stage two of the programming operation, which is intended to compact the threshold voltage distributions in order to achieve the desired distribution parameters (e.g., distribution width), as described in more detail herein below.

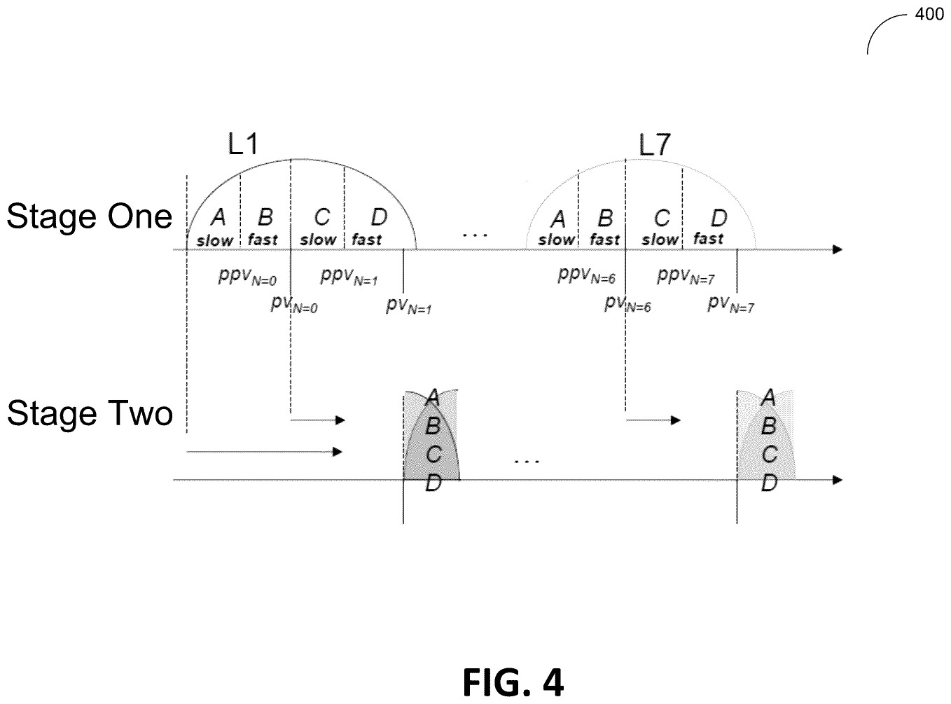

Alternatively, stage two of the programming operation can employ the analog selective slow program convergence (ASSPC) technique, which, instead of using a uniform bitline voltage, uses an analog or continuous voltage applied to the bitline (“analog bitline voltage level” or “continuous bitline voltage level”). Thus, the bitline voltage is biased continuously starting from the time of the threshold voltage of the associated memory cells reaching a corresponding pre-program verify threshold voltage until the bitline voltage reaches the fixed value at the time of threshold voltage of the associated memory cell reaching a program verify threshold voltage, as described in more detail herein below with reference to FIG. 4.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an implementation. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), can be a memory controller or other external host device.

Memory device 130 includes an array of memory cells 104 logically arranged in rows and columns. Memory cells of a logical row are typically connected to the same wordline, while memory cells of a logical column are typically selectively connected to the same data line (e.g., a bitline). A single wordline can be associated with more than one logical row of memory cells and a single data line can be associated with more than one logical column. Memory cells (not shown in FIG. 1B) of at least a portion of array of memory cells 104 are capable of being programmed to one of at least two target data states.

Row decode circuitry 108 and column decode circuitry 111 are provided to decode address signals. Address signals are received and decoded to access the array of memory cells 204. Memory device 130 also includes input/output (I/O) control circuitry 112 to manage input of commands, addresses and data to the memory device 130 as well as output of data and status information from the memory device 130. An address register 114 is in communication with I/O control circuitry 112 and row decode circuitry 108 and column decode circuitry 111 to latch the address signals prior to decoding. A command register 124 is in communication with I/O control circuitry 112 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 204. The local media controller 135 is in communication with row decode circuitry 108 and column decode circuitry 111 to control the row decode circuitry 108 and column decode circuitry 111 in response to the addresses. In some implementations, local media controller 135 includes programming manager 134, which can implement the memory programming operations with respect to memory device 130, as described herein.

The local media controller 135 is also in communication with a cache register 218. Cache register 118 latches data, either incoming or outgoing, as directed by the local media controller 135 to temporarily store data while the array of memory cells 104 is busy writing or reading, respectively, other data. During a programming operation (e.g., a write operation), data can be passed from the cache register 118 to the data register 121 for transfer to the array of memory cells 204; then new data can be latched in the cache register 118 from the I/O control circuitry 212. During a read operation, data can be passed from the cache register 118 to the I/O control circuitry 112 for output to the memory sub-system controller 115; then new data can be passed from the data register 121 to the cache register 218. The cache register 118 and/or the data register 121 can form (e.g., can form a portion of) a page buffer of the memory device 130. A page buffer can further include sensing devices (not shown in FIG. 1B) to sense a data state of a memory cell of the array of memory cells 204, e.g., by sensing a state of a bitline connected to that memory cell. A status register 122 can be in communication with I/O control circuitry 112 and the local memory controller 135 to latch the status information for output to the memory sub-system controller 115.

Memory device 130 receives control signals at the memory sub-system controller 115 from the local media controller 135 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 132 depending upon the nature of the memory device 130. In some implementations, memory device 130 receives command signals (which represent commands), address signals (which represent addresses), and data signals (which represent data) from the memory sub-system controller 115 over a multiplexed input/output (I/O) bus 136 and outputs data to the memory sub-system controller 115 over I/O bus 136.

For example, the commands can be received over input/output (I/O) pins [7:0] of I/O bus 136 at I/O control circuitry 112 and can then be written into command register 224. The addresses can be received over input/output (I/O) pins [7:0] of I/O bus 136 at I/O control circuitry 112 and can then be written into address register 214. The data can be received over input/output (I/O) pins [7:0] for an 8-bit device or input/output (I/O) pins [15:0] for a 16-bit device at I/O control circuitry 112 and then can be written into cache register 218. The data can be subsequently written into data register 121 for programming the array of memory cells 204.

In some implementations, cache register 118 can be omitted, and the data can be written directly into data register 220. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the memory sub-system controller 115), such as conductive pads or conductive bumps as are commonly used.

In some implementations, additional circuitry and signals can be provided, and that the memory device 130 of FIG. 1B has been simplified. It should be recognized that the functionality of the various block components described with reference to FIG. 1B can not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) can be used in the various implementations.

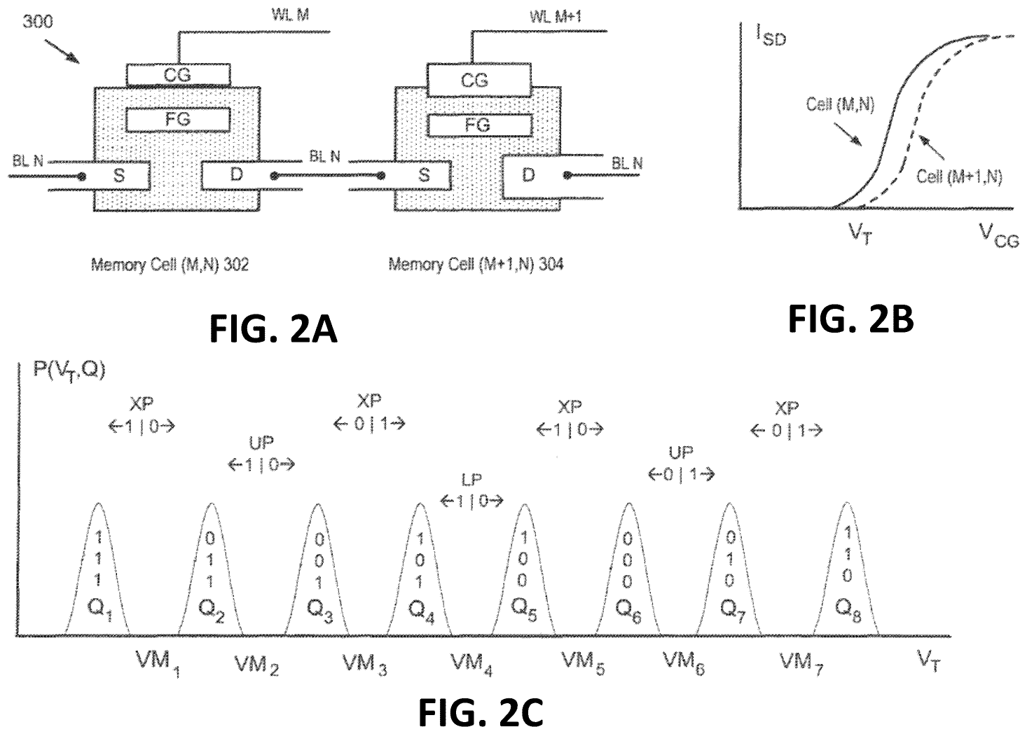

One or more memory devices of the memory sub-system 100 can be represented, e.g., by NAND memory devices that utilize transistor arrays built on semiconductor chips. As illustrated schematically in FIG. 2A, a memory cell of a memory device can be a transistor, such as metal-oxide-semiconductor field effect transistor (MOSFET), having a source(S) electrode and a drain (D) electrode to pass electric current there through. The source and drain electrodes can be connected to a conductive bitline (BL), which can be shared by multiple memory cells. A memory device can include an array or memory cells that are connected to a plurality of wordlines (WL) and a plurality of bitlines (BL). A memory device can further include circuitry for selectively coupling WLs and BLs to voltage sources providing control gate and source-drain signals.

Referring again to FIG. 2A, memory cells 302 and 304 can be connected to the same bitline N and two different conductive wordlines, M and M+1, respectively. A memory cell can further have a control gate (CG) electrode to receive a voltage signal V_{CG} to control the magnitude of electric current flowing between the source electrode and the drain electrode. More specifically, there can be a threshold control gate voltage V_{T} (herein also referred to as “threshold voltage” or simply as “threshold”) such that for V_{CG}<V_{T}, the source-drain electric current can be low, but can increase substantially once the control gate voltage has exceeded the threshold voltage, V_{CG}>V_{T}. Transistors of the same memory device can be characterized by a distribution of their threshold voltages, P(V_{T})=dW/dV_{T}, so that dW=P(V_{T})dV_{T} represents the probability that any given transistor has its threshold voltage within the interval [V_{T}, V_{T}+dV_{T}]. For example, FIG. 2B illustrates schematically dependence of the source-drain current I_{SD} on the control gate voltage for two memory cells, e.g. memory cell 302 (solid line) and memory cell 304 (dashed line), having different threshold control gate voltages.

To make a memory cell non-volatile, the cell can be further equipped with a conducting island-a charge storage node—that can be electrically isolated from the control gate, the source electrode, and the drain electrode by insulating layers (depicted in FIG. 2A as the dotted region). In response to an appropriately chosen positive (in relation to the source potential) control gate voltage V_{CG}, the charge storage node can receive an electric charge Q, which can be permanently stored thereon even after the power to the memory cell—and, consequently, the source-drain current—is ceased. The charge Q can affect the distribution of threshold voltages P(V_{T},Q). Generally, the presence of the electric charge Q shifts the distribution of threshold voltages towards higher voltages, compared with the distribution P(V_{T}) for an uncharged charge storage node. This happens because a stronger positive control gate voltage V_{CG can} be needed to overcome a negative potential of the charge storage node charge Q. If any charge of a sequence Qₖ of charges with 1≤k≤2^{N can} be selectively programmed (and later detected during a read operation) into a memory cell, the memory cell can function as an N-bit storage unit. The charges Qₖ are preferably selected to be sufficiently different from each other, so that any two adjacent voltage distributions P(V_{T}, Qₖ) and P(V_{T}, Qₖ₊₁) do not overlap being separated by a valley margin, so that 2^{N} distributions P(V_{T}, Qₖ) are interspaced with 2^{N}−1 valley margins.

FIG. 2C illustrates schematically a distribution of threshold control gate voltages for a memory cell capable of storing three bits of data by programming the memory cell into at least eight charge states (also referred to as “programming levels”) that differ by the amount of charge on the cell's charge storage node. FIG. 2C shows distributions of threshold voltages P(V_{T}, Qₖ) for 2^{N}=8 different charge states of a tri-level cell (TLC) separated with 2³−1=7 valley margins VMₖ. Accordingly, a memory cell programmed into a charge state k-th (i.e., having the charge Qₖ deposited on its charge storage node) can be storing a particular combination of N bits (e.g., 0110, for N=4). This charge state Qₖ can be determined during a readout operation by detecting that a control gate voltage V_{CG} within the valley margin VMₖ is sufficient to open the cell to the source-drain current whereas a control gate voltage within the preceding valley margin VMₖ₋₁ is not.

Memory devices can be classified by the number of bits stored by each cell of the memory. For example, a single-level cell (SLC) memory has cells that can each store one bit of data (N=1). A multi-level cell (MLC) memory has cells that can each store up to two bits of data (N=2), a tri-level cell (TLC) memory has cells that can each store up to three bits of data (N=3), and a quad-level cell (QLC) memory has cells that can each store up to four bits of data (N=4). In general, the operations described herein can be applied to memory devices having N-bit memory cells, where N>1.

For example, a TLC can be capable of being in one of eight charging states Qₖ (where the first state is an uncharged state Q₁=0) whose threshold voltage distributions are separated by valley margins VMₖ that can be used to read out the data stored in the memory cells. For example, if it is determined during a read operation that a read threshold voltage falls within a particular valley margin of 2^{N}−1 valley margins, it can then be determined that the memory cell is in a particular charge state out of 2^{N} possible charge states. By identifying the right valley margin of the cell, it can be determined what values all of its N bits have. The identifiers of valley margins (such as their coordinates, e.g., location of centers and widths) can be stored in a read level threshold register of the memory controller 215.

As noted herein above, the memory controller 215 can program a state of the memory cell and then read can read this state by comparing a read threshold voltage V_{T} of the memory cell against one or more read level thresholds. The read operation can be performed after a memory cell is placed in one of its charged states by a previous programming operation, which can include one or more programming passes. Each programming pass would apply appropriate programming voltages to a given wordline in order place appropriate charges on the charge storage nodes of the memory cells that are connected to the wordline.

A programming operation involves a sequence of programming voltage pulses that are applied to a selected wordline. Referring again to FIG. 2A, the source(S) and drain (D) electrodes of a memory cell can be connected to a conductive bitline shared by multiple memory cells. A programming operation would apply a sequence of programming voltage pulses to the control gate (CG) via a corresponding wordline (WL). Each programming voltage pulse would induce an electric field that would pull the electrons onto the charge storage node. After each programming pulse is applied to the selected wordline, a verify operation can be performed by reading the memory cell in order to determine whether the threshold voltage V_{T} of the memory cell has reached a desired value (voltage verify level). If the threshold voltage V_{T} of the memory cell has reached the verify voltage associated with the desired state, the bitline to which the memory cell is connected can be biased at the program inhibit voltage, thus inhibiting the memory cells that are coupled to the bitline from being further programmed, i.e., to prevent the threshold voltage V_{T} of the memory cells from shifting further upward in response to subsequent programming pulses applied to the selected wordline.

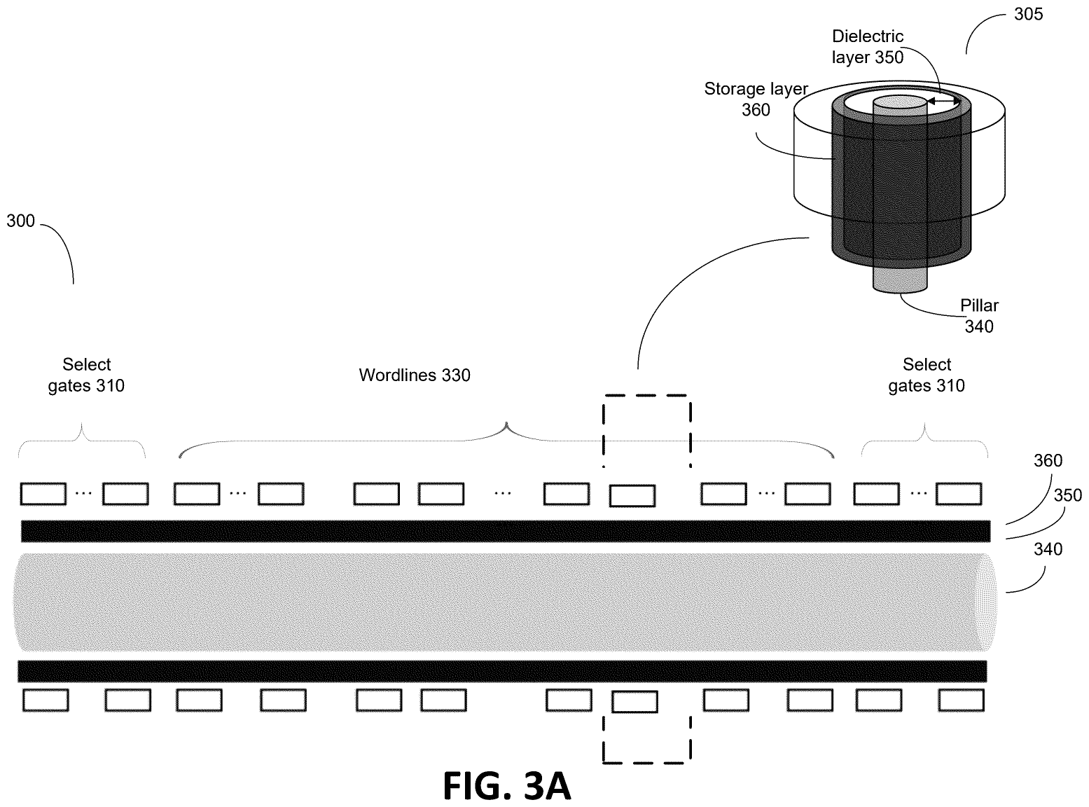

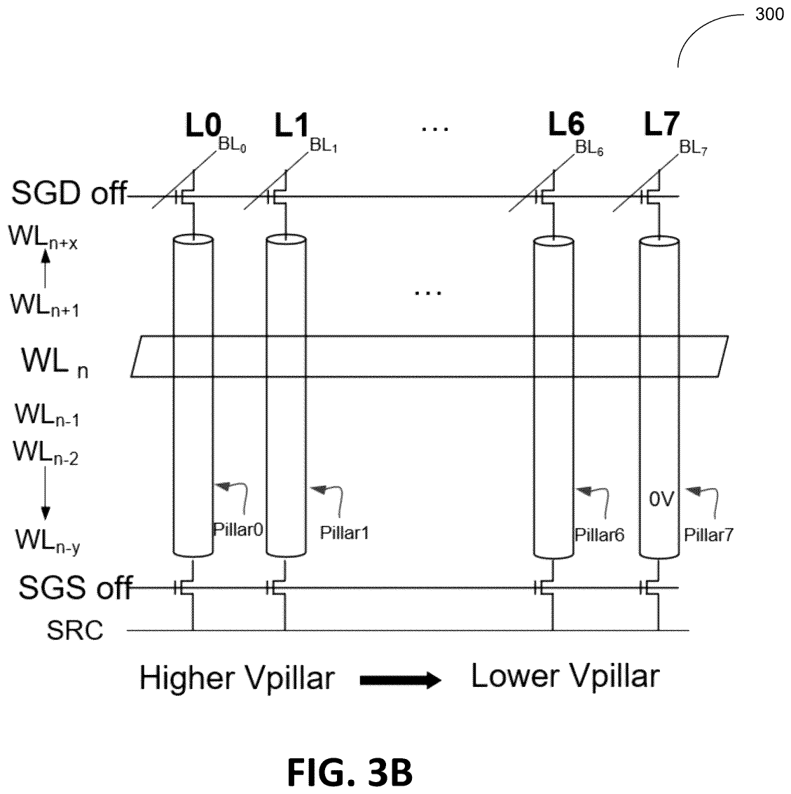

FIG. 3A schematically illustrates a three-dimensional structure of an example memory cell string of a memory device operating in accordance with implementations of the present disclosure. As shown in FIG. 3A, an example memory device can include a memory cell string 300 comprising multiple memory cells 305 sharing a common pillar 340, dielectric layer 350, and storage layer 360. The memory cells can be electrically coupled to wordlines 330. Select gates 310 can control coupling of the pillar 340 to respective bitlines.

FIG. 3B illustrates an example set of pillars of an example memory array operating in accordance with implementations of the present disclosure. As shown in FIG. 3B, the example memory array 350 of a TLC memory device includes wordlines (e.g., a target wordline (WLn), a first set of unselected wordlines (e.g., WLn−1 and WLn+1 to WLn+x), a second set of unselected wordlines (e.g., WLn−2 to WLn-y) and a set of bitlines (e.g., BL0 to BL7) corresponding to an erase level (L0) and multiple programming levels (L1, . . . . L7) to be programmed in accordance with one or more implementations of the present disclosure. As shown in FIG. 3B, the memory array 350 can be arranged in rows (each corresponding to a wordline) and columns (each corresponding to a bitline), wherein the intersection of a wordline and bitline constitutes the address of the memory cell. Each column can include a string of series-connected memory cells connected (e.g., selectively connected) to a common source (SRC). The common source can be coupled to a reference voltage (e.g., ground voltage or simply “ground” (Gnd) or a voltage source (e.g., a charge pump circuit or power supply which can be selectively configured to a particular voltage suitable for optimizing a programming operation, for example). A string of memory cells can be connected in series between a first select transistor (e.g., a source-side select transistor) referred to as a source select gate (SGS) and a second select transistor (e.g., a drain-side select transistor) referred to as a drain select gate (SGD). The source select transistors can be commonly connected to a first select line (e.g., a source select line) and the drain select transistors can be commonly connected to a second select line (e.g., a drain select line).

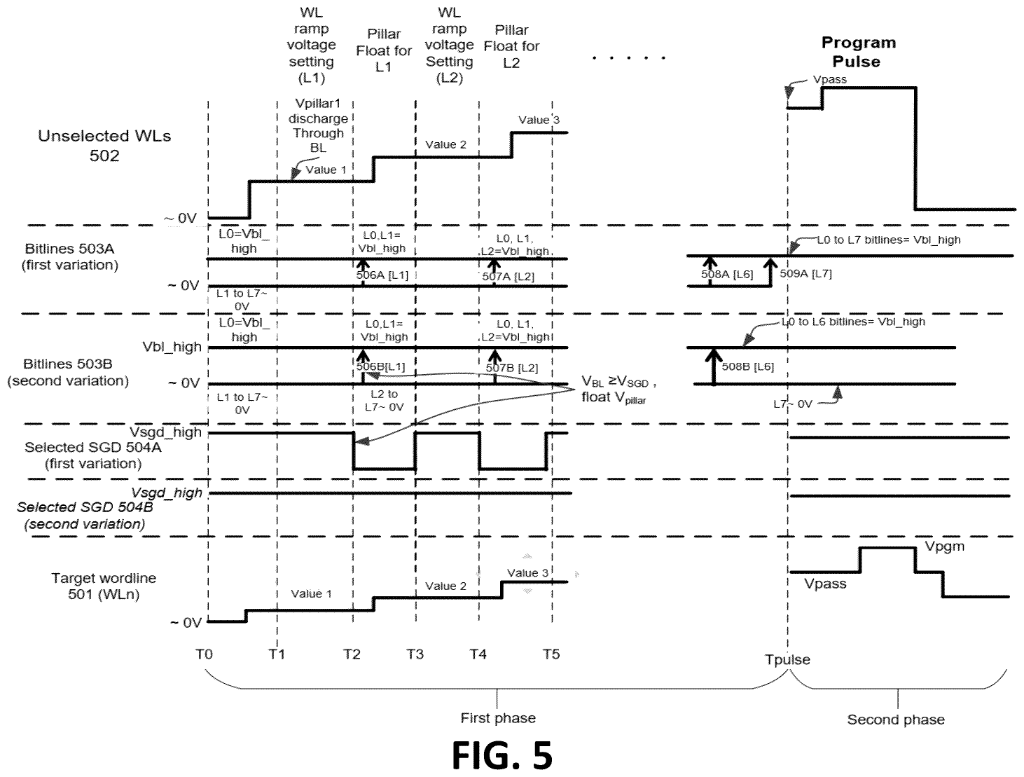

As shown in FIG. 3B, the memory array 350 includes a set of pillars (e.g., Pillar0, Pillar1 . . . . Pillar7) corresponding to substantially vertical strings of series coupled memory cells of the memory array 350. In some implementations, the pillars refer to the channel regions (e.g., composed of polysilicon) of the access transistors of a vertical string of memory cells. In some implementations, each of the pillars can be floated and a corresponding voltage can be boosted at different voltage levels (V_{PILLAR}) at different times by turning the source-side select transistor (SGS) and the drain-side select transistor (SGD) off. In some implementations, the channel region is first discharged to ground before being floated and boosted to a particular voltage. In some implementations, once a respective pillar is floated, a voltage of each pillar (V_{PILLAR}) can be boosted or increased in accordance with a step or increase of a ramping wordline voltage, as described in greater detail with respect to FIG. 5.

FIG. 4 schematically illustrates a high-level overview of a two-stage programming operation implemented in accordance with implementations of the present disclosure. As schematically illustrated by FIG. 4, the example programming operation 400 includes two stages: Stage One and Stage Two, such that each stage involves one or more programming pulses followed by respective verification operations.

Stage one of the programming operation utilizes the all-level programming (ALP) technique, which places, for each logical level (e.g., L1-L7 for triple-level cell (TLC), as illustrated), the corresponding threshold voltage distribution of the target memory cells to the vicinity of the desired position defined by the corresponding program verify voltage level(s). In some implementations, the desired position of the center of a threshold voltage distribution for a given logical level (L1-L7) matches the program verify voltage for that logical level. In the illustrative example of FIG. 4, the desired position of the center of L1 threshold voltage distribution matches the program verify voltage PV_{N=1}, and the desired position of the center of L7 threshold voltage distribution matches the program verify voltage PV_{N=7}.

In some implementations, stage one of the programming operation simultaneously programs the target memory cells at multiple logical levels by boosting the pillars in a staggered manner, while ramping up the voltage applied to the unselected wordlines to the pass voltage level and the voltage applied to the selected wordlines to the programming voltage level, as described in more detail herein below.

Stage one of the programming operation can further involve classifying the memory cells by their respective positions in the resulting threshold voltage distributions, which can be done based on the results of the program verify operations performed after the programming pulse(s) of stage one of the programming operation.

In some implementations, the memory cells of a threshold voltage distribution for a given logical level can be classified into a pre-defined number of sections based on the program verify voltages and pre-program verify voltages of that logical level and the previous logical level. In the illustrative example of FIG. 4, the memory cells of L7 threshold voltage distribution can be classified into four sections (denoted A, B, C, D) based on the program verify voltages and pre-program verify voltages of L7 and L6.

Stage two of the programming operation compacts the threshold voltage distributions in order to achieve the desired distribution parameters (e.g., the distribution width). In some implementations, stage two employ the selective slow program convergence (SSPC) technique, which can utilize the results of the above-described memory cell classification in order to assign, to each memory cell or group of memory cells, a corresponding bitline bias for seeding the pillar during stage two of the programming operation, which is intended to compact the threshold voltage distributions in order to achieve the desired distribution parameters (e.g., distribution width), as described in more detail herein below.

In the illustrative example of FIG. 4, for the memory cells in section A of L7 threshold voltage distribution, the bitline voltage V_{BL} is set to 0V and the boost voltage V_{BOOST} is set to 0V; for the memory cells in section B of L7 threshold voltage distribution, the bitline voltage V_{BL} is set to the value of V_{BL} FAST and the boost voltage V_{BOOST} is set to 0V; for the memory cells in section C of L7 threshold voltage distribution, the bitline voltage V_{BL} is set to 0V and the boost voltage is set to V_{BOOST}; and for the memory cells in section D of L7 threshold voltage distribution, the bitline voltage V_{BL} is set to V_{BL} FAST and the boost voltage is set to V_{BOOST}.

Alternatively, stage two of the programming operation can employ the analog selective slow program convergence (ASSPC) technique, which, instead of using a uniform bitline voltage, uses an analog or continuous voltage applied to the bitline (“analog bitline voltage level” or “continuous bitline voltage level”). Thus, the bitline voltage is biased continuously starting from the time of the threshold voltage of the associated memory cells reaching a corresponding pre-program verify threshold voltage until the bitline voltage reaches the fixed value at the time of threshold voltage of the associated memory cell reaching a program verify threshold voltage, as described in more detail herein below.

FIG. 5 illustrates example voltage waveforms of various portions of a memory array during execution of an ALP programming operation in accordance with implementations of the present disclosure. In some implementations, the portions of the memory array include a set of memory cells associated with a target wordline 501 (WLn) and portions of corresponding voltage waveforms resulting from execution of stage one of a two-stage programming operation, according to implementations of the present disclosure. In some implementations, the processing logic identifies a set of memory cells (e.g., target wordline 501 (WLn)) to be programmed by stage one of a two-stage programming operation. In some implementations, stage one of a two-stage programming operation includes a wordline ramping phase followed by a programming pulse phase.

The wordline ramping phase (starting from time TO) applies ramping wordline voltage to a set of wordlines (e.g., target wordline 501 and a set of one or more unselected wordlines 502). For example, as shown in FIG. 5, a ramping wordline voltage is applied to wordline 501 where the voltage is incrementally ramped from 0V to 3V between T0 and T5. While the ramping wordline voltage is applied, a set of pillars corresponding to different programming levels are sequentially floated (e.g., by uncoupling the set of pillars in operation 330). In some implementations, a second set of unselected wordlines (e.g., WLn-2 and below) are set to 0V (e.g., the voltage of the source select gate (V_{SGS}) is 0V, and V_{UNSEL_SGD}=0V).

With reference to FIG. 3B, at the end of the wordline ramping phase, the pillar voltage levels (V_{PILLAR}) are boosted to different voltage levels (e.g., V_{PILLAR} for programming level L1 is boosted to a highest value, V_{PILLAR} for programming level L2 is boosted to a next highest value and so on to V_{PILLAR} for programming level L7 which remains approximately 0V during the wordline ramping phase).

In some implementations, prior to the wordline ramping phase shown in FIG. 5 (e.g., prior to the application of the ramping wordline voltage), the pillar associated with the erase level (L0) is floated, a bitline 503A (according to a first variation), 503B (according to a second variation) corresponding to L0 is set to V_{BL_HIGH}, and a selected SGD (Sel_SGD 504A, Sel_SGD 504B) is set to V_{SGD_HIGH}. In some implementations, the selected SGD can be toggled between V_{SGD_HIGH} to a ground (e.g., approximately 0V), as shown with respect to a first waveform corresponding to Sel_SGD 504A. In accordance with another implementation, the selected SGD can remain at V_{SGD_HIGH} during the wordline ramping phase, as shown with respect to a second waveform corresponding to Sel_SGD 504B. In some implementations, the use of sel_SGD 504A (e.g., the toggling variation) is a first variation that can be implemented by the processing logic. In another implementation, the use of Sel_SGD 504B (e.g., the variation wherein Sel_SGD 504B remains at V_{SGD_HIGH}) is a second variation that can be implemented by the processing logic.

As shown in FIG. 5, between time T0 and T1, a first ramp of the ramping wordline voltage (e.g., from approximately 0V to value 1, in accordance with the step voltage) is applied. During a time between T1 and T2, the ramping wordline voltage is applied to a first pillar (e.g., Pillar1 of FIG. 3B) corresponding to programming level L1. In some implementations, during this time period, the voltage of Pillar1 (V_{PILLAR1}) is discharged through the bitline 503A, 503B corresponding to L1 which is set to ground (e.g., approximately 0V).

In some implementations, a selected SGD 504A and the voltage levels of the bitlines 503A, 503B can be used to float the pillars in sequence and boost the corresponding pillar voltages (e.g., V_{PILLAR}) when each respective pillar is in the floating state. As shown in FIG. 5, during a first time period (e.g., T0 to T2), a voltage level applied to a selected SGD 504A (V_{SGD})) is a high source voltage level (V_{SGD_HIGH}). In some implementations, as shown in FIG. 5, at time T2, the selected SGD 504A can be toggled from V_{SGD_HIGH} to ground (e.g., approximately 0V) in order to float the first pillar (e.g., Pillar1 of FIG. 3B) corresponding programming level L1. As shown in FIG. 5, at time t2, the toggling of the selected SGD 504A from V_{SGD_HIGH} to ground (e.g., approximately 0V) disconnects Pillar1 and floats the voltage of Pillar1 (V_{PILLAR1}) corresponding to programming level L1. In some implementations, in response to or following the toggling of V_{SGD} (e.g., toggling the selected SGD 504A), the L1 bitline is caused to toggle from ground (e.g., 0V) to a high voltage (V_{BL_HIGH}), as illustrated by the arrow 506A for the first variation and arrow 506B for the second variation. In some implementations, the toggling of the L1 bitline to V_{BL_HIGH} ensures Pillar1 is floated and V_{PILLAR_1} can be boosted in accordance with the wordline ramping level at the time of the floating. In some implementations, Pillar1 is floated when the voltage of the bitline (V_{BL}) is greater than or equal to V_{SGD}).

In the example shown in FIG. 5, the V_{PILLAR1} is boosted while Pillar1 is floated (e.g., in the floating state) and exposed to a longest relative duration of the application of the ramping wordline voltage to the target wordline, wherein the ramping wordline voltage is periodically increased or stepped by a wordline step voltage level. In this example, the V_{PILLAR1} remains floating from T2 to the end of the wordline ramping phase (e.g., in view of the setting of the corresponding bitline to V_{BL_HIGH}) and is repeatedly boosted by the ramping wordline voltage each time the ramping wordline voltage is ramped or increased. At the end of the wordline ramping phase, V_{PILLAR1} is boosted by the wordline step voltage (or a preset boost ratio of the wordline step voltage). For example, the V_{PILLAR1} is boosted to value 7 (e.g., approximately 7V) after completion of the wordline ramping phase (e.g., V_{PILLAR1}=[total ramping wordline voltage (e.g., approximately 8V)]−[the wordline voltage level at the time V_{PILLAR1} is floated (e.g., 1V)]).

In some implementations, as shown in FIG. 5, following the toggling of the selected SGD 504A (at time T2), and the corresponding increase of the L1 bitline voltage level from approximately 0V to V_{BL_HIGH} (as illustrated by arrow 506A for the first variation and arrow 506B for the second variation), the bitline voltage level (e.g., V_{BL}) is greater than the V_{SGD}, resulting in Pillar1 remaining in a floating state and subject to boosting by the ramping wordline voltage until the end of the wordline ramping phase

As shown in FIG. 5, the floating of respective pillars continues for each of the set of pillars (e.g., pillars corresponding to L1 to L6) to enable each V_{PILLAR} to be boosted in accordance with the ramping wordline voltage. For example, at time T3, the selected SGD 504A is toggled from approximately 0V to V_{SGD_HIGH} to enable the setting of the ramping wordline voltage in accordance with a next step or increase. It is noted that the SGD 504A is shared between the various strings and pillars such that the toggling of the SGD 504A from low to high (e.g., at time T3) does not affect V_{PILLAR1} (e.g., the V_{PILLAR} for the pillars floated prior to the toggling of SGD 504A from low to high are not affected). As shown in FIG. 5, during a time period between T3 and T4 when the selected SGD 504A is V_{SGD_HIGH} and V_{BL2} is approximately 0V, value 2 of the ramping wordline voltage is applied. At time T4, Pillar2 is floated by toggling the selected SGD 504A from V_{SGD_HIGH} to ground (e.g., approximately 0V). In some implementations, following the toggling of the selected SGD 604A to V_{SGD_HIGH}, the L2 bitline toggles from ground (e.g., approximately 0V) to V_{BL_HIGH}, as illustrated by the arrow 507A for the first variation and arrow 507B for the second variation. In some implementations, the toggling of the L2 bitline to the inhibit voltage level maintains the floating of Pillar2 for the remainder of the wordline ramping phase.

In some implementations, as the ramping wordline voltage is applied, each of the pillars of a set of pillars (e.g., Pillar1 to Pillar6 in FIG. 3B) are floated in sequence. With reference to FIG. 3B, in some implementations, a voltage of the pillar corresponding to the erase state (Pillar0) is floated prior to the application of the ramping wordline voltage. For example, Pillar 1 is floated at a first time during application of the ramping wordline voltage, Pillar 2 is floated at a second time during application of the ramping wordline voltage, and so on.

In some implementations, while a respective pillar is in the floated state, a voltage corresponding to that pillar is boosted by the ramping wordline voltage. For example, Pillar 1 is floated at a first time and is boosted to a pillar voltage level corresponding to each increase of the ramping wordline voltage (e.g., each time the ramping wordline voltage is stepped). In this example, since Pillar 1 is floated at a first time, the corresponding pillar voltage (e.g., V_{PILLAR1}) is boosted multiple times in accordance with each increase of the ramping wordline voltage until the end of the wordline ramping phase of stage one of a two-stage programming operation.

In some implementations, as shown in FIG. 3B, since the pillars are floated in sequence (e.g., Pillar1 is floated before Pillar2, Pillar2 is floated before Pillar3, and so on), the respective pillar voltages are boosted from higher levels to lower levels moving from left to right in FIG. 3B. In this regard, V_{PILLAR1} is higher than V_{PILLAR2}, V_{PILLAR2} is higher than V_{PILLAR3}, and so on as a function of the time when each pillar is floated. In some implementations, the V_{PILLAR} for a floated pillar is boosted to a higher voltage level each time the ramping wordline voltage increases. As such, pillars that are floated earlier are boosted by a greater number of wordline ramping increases.

Although the portion of the waveforms shown in FIG. 5 relate to the floating of Pillar1 and Pillar2, it is to be appreciated the operations described can be repeated as part of stage one of a two-stage programming operation to float the pillars to move or adjust the corresponding V_{PILLAR} levels for each of the remaining programming levels (e.g., L3 to L7 for a TLC memory device) according to the first variation. As shown, according to the first variation, the L6 bitline toggles from ground (e.g., approximately 0V) to V_{BL_HIGH}, as illustrated by the arrow 508A and the L7 bitline toggles from ground (e.g., approximately 0V) to V_{BL_HIGH}, as illustrated by the arrow 509A.

In another implementation, according to the second variation, Pillar7 corresponding to programming level L7 is not floated due to the corresponding V_{PILLAR} being approximately 0V. For example, at the end of the wordline ramping phase, V_{PILLAR1} is boosted to a first value (e.g., 6V), wherein V_{PILLAR1}=[total ramping wordline voltage (e.g., VPASS)]−[the wordline voltage level at the time Pillar1 is floated (e.g., value 1)], V_{PILLAR2} is boosted to a second value (e.g., 5V), wherein V_{PILLAR} 2=[total ramping wordline voltage (e.g., VPASS)]−[the wordline voltage level at the time V_{PILLAR2} is floated (e.g., value 2)], V_{PILLAR3} is boosted to a third value (e.g., 4V), wherein V_{PILLAR} 3=[total ramping wordline voltage (e.g., VPASS)]−[the wordline voltage level at the time V_{PILLAR3} is floated (e.g., value 3)], and so on. As shown in FIG. 5, according to the second variation, the L6 bitline toggles from ground (e.g., approximately 0V) to V_{BL_HIGH}, as illustrated by the arrow 508B. Accordingly, the boosted V_{PILLAR} is established for each respective pillar.

According to an implementation, L0 through L7 are approximately 8V (or higher), 6V, 5V, 4V, 3V, 2V, 1V, 0V, respectively. In some implementations, V_{PILLAR} of L0 is equal to VPASS (e.g., between 8V and 10V). In some implementations, there is a gap between V_{PILLAR} of L0 and the V_{PILLAR} of L1 (e.g., a gap of 2V or higher). In some implementations, since V_{PILLAR} of L7 is approximately 0V, 1V can be added for each level such that the V_{PILLAR} S of L1 through L7 are 6V through approximately 0V.

In some implementations, at the end of the wordline ramping phase (e.g., at T_{PULSE}), the wordlines 501, 502 are ramped to a pass voltage level (VPASS). In some implementations, the unselected wordlines are ramped in seven ramping levels to VPASS for fine tuning the V_{PILLAR} (e.g., pillar potential). At time Tn, different programming stress levels have been applied to corresponding programming level (Ln), as represented by the following expression:

V_{STRESSLEVEL(Ln)}=V_{PGM_WL}-V_{PILLAR},

where V_{PILLAR}=(V_{PASS}−V_{WL_TIME_OF_FLOAT})×BOOST_RATIO,
where V_{WL_TIME_OF_FLOAT} is the voltage level of the ramping wordline voltage at the time the pillar (Pillar_n) corresponding to the programming level (Ln) is floated; and wherein the BOOST_RATIO is a preset value (e.g., 1, 0.8, 0.6, etc.) corresponding to an amount of boost to the V_{PILLAR} as a function of the ramping wordline voltage.

In some implementations, in accordance to the second variation noted above, the selected SGD 504B can be maintained at V_{SGD_HIGH}. According to this variation, as shown in FIG. 5, the selected SGD 504B remains at V_{SGD_HIGH} during the wordline ramping phase of the programming operation (e.g., the selected SGD 504B is not toggled). According to this variation, with the selected SGD 504B remaining at V_{SGD_HIGH}, the floating of each pillar is initiated by toggling the voltage (V_{BL}) of the bitline 503 corresponding to a respective pillar from approximately 0V to V_{BL_HIGH}. For example, the L1 bitline can be toggled from ground (e.g., 0V) to a high voltage (V_{BL_HIGH}), as illustrated by the arrow 506, in order to float Pillar1. In some implementations, the toggling of the L1 bitline to V_{BL_HIGH} ensures Pillar1 is floated and V_{PILLAR1} can be boosted in accordance with the wordline ramping level at the time of the floating, and repeatedly boosted each time the wordline ramping level increases.

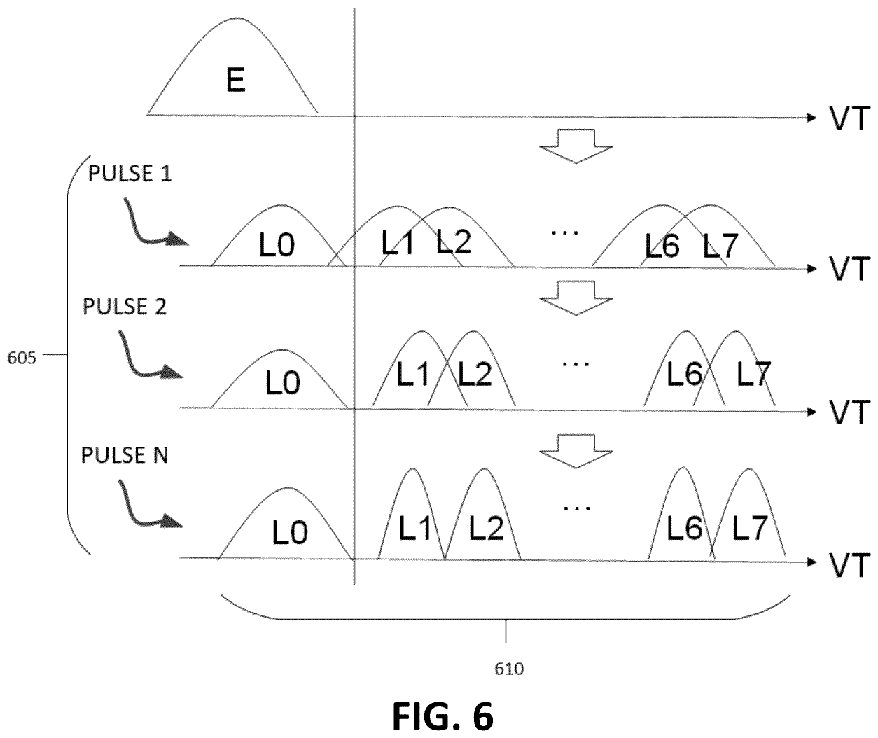

FIG. 6 illustrates an example ALP programming operation including a set of multiple pulses 605 (e.g., pulse 1, pulse 2 . . . pulse N) applied to program all programming levels (e.g., L1, L2, . . . . L7) of a specified set of memory cells of the memory array, according to implementations of the present disclosure. As shown in FIG. 6, each respective pulse (e.g., Pulse 1, Pulse 2 . . . and Pulse N) is used to program each of programming levels (e.g., L1 to L7) of a memory device in a memory sub-system in accordance with one or more implementations of the present disclosure. In some implementations, each pulse programs an entire set of program levels 610 of the memory cells together. In some implementations, the set of pulses 605 are applied to a target wordline (e.g., WLn) associated with the set of memory cells to be programmed, as shown and described with reference to FIGS. 4-6.

As shown in FIGS. 5 and 6, during the programming pulse phase of the programming operation, a first programming pulse (e.g., Pulse 1 of FIG. 6) is applied at time Tpulse of FIG. 5. In some implementations, the first programming pulse programs each of the programming levels (e.g., L1 to L7). In some implementations, a programming voltage (Vpgm) of each pulse is applied to the selected wordline 501 to program each of the levels (L1 to L7 of a TLC memory device). In some implementations, for the memory cells in a selected page, the same Vpgm_WL is applied on the programming pulse phase Vpgm. However, different V_{PILLARS} are set up during the wordline ramping phase depending on the corresponding target data level. In some implementations, the different V_{STRESSLEVELS} are applied on the memory cells of L1 to L7. In some implementations, a series of programming pulses (e.g., as shown in FIG. 6 as applied to the target wordline 501) to complete the programming of the set of programming levels. In some implementations, for each pulse of the set of pulses applied, a program verify operation can be performed for each programming level to verify that target voltage corresponding to each respective programming level has been reached.

In the examples shown in FIGS. 5-6, a set of programming pulses are applied to a selected wordline (WLn). In some implementations, a first set of unselected wordlines including WLn−1 and WLn+1 through WLn+x, as shown in FIG. 3B, are ramped to a pass voltage (VPASS) for programming levels L1 to L7 (e.g., WLn+1 and above are ramped in seven levels to VPASS for fine tuning the corresponding pillar potential). In some implementations, the pillar potential can stay on approximately 0V through a conduction with corresponding bitline for L7 program or be inhibited on any of the seven voltages (e.g., between 0V and V_{PASS}) for L0˜L6 program, depending on user data levels. In some implementations, a second set of unselected wordlines including WLn-2 through WLn-y are set to 0V (e.g., SGS˜0V, SGD˜0V).

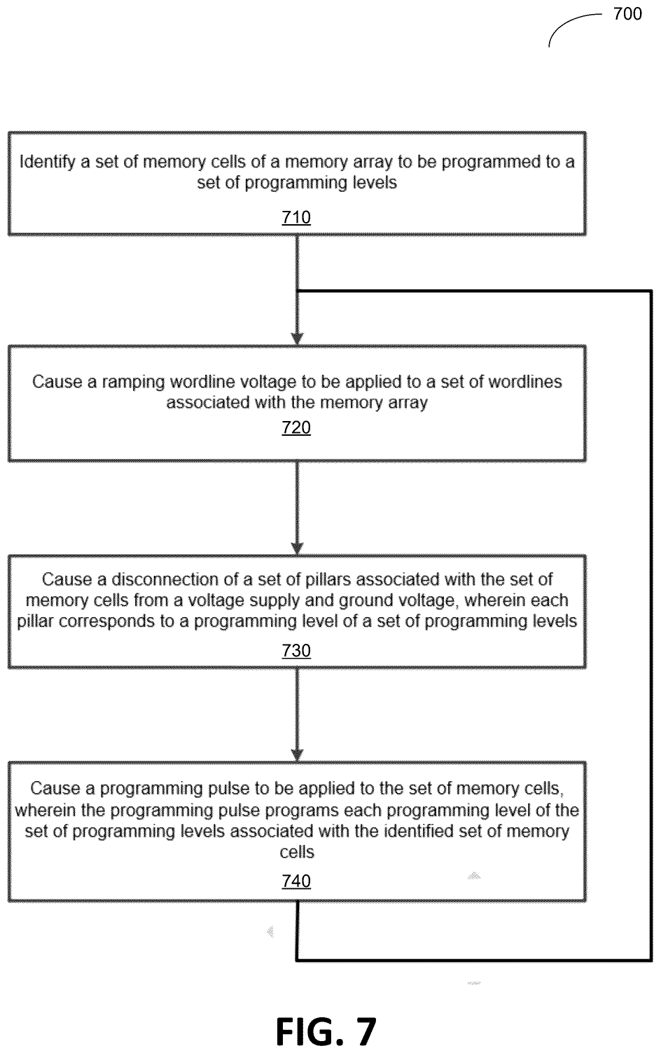

FIG. 7 is a flow diagram of an example method of performing an ALP operation, in accordance with implementations of the present disclosure. The method 700 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some implementations, the method 700 is performed by the memory sub-system controller 115 and/or the local media controller 135 of FIGS. 1A-1B. Although shown in a particular sequence or order, unless otherwise specified, the order of the operations can be modified. Thus, the illustrated implementations should be understood only as examples, and the illustrated operations can be performed in a different order, and some operations can be performed in parallel. Additionally, one or more operations can be omitted in various implementations. Thus, not all operations are required in every implementation. The voltage corresponding voltage waveforms are schematically illustrated by FIG. 5.

At operation 710, the controller implementing the method identifies one or more a memory cells to be programmed. In an illustrative example, the program manager 134 implemented by the local media controller 135 of FIGS. 1A-1B can receive, from the memory interface 113 of the memory sub-system controller 115, a request to perform a memory programing operation to program the identified memory cells to a specified logical level. The identified memory cells can be addressable by a target wordline and a set of target bitlines, as described in more detail herein above.

At operation 720, a ramping up voltage is applied to one or more wordlines of the memory array (e.g., ramping wordline voltage applied to target wordline 501, as described in detail with reference to FIG. 5). In an implementation, the ALP operation includes a first phase wherein an increasing or ramping wordline voltage (e.g., a voltage applied to one or more wordlines that is periodically ramped or increased by a wordline step voltage) is applied to a set of wordlines of the memory array (e.g., a selected wordline corresponding to the set of identified memory cells to be programmed and one or more unselected wordlines). For example, upon identifying a set of memory cells to be programmed (e.g., the memory cells associated with one or more wordlines of a memory array identified in operation 710), control logic of the memory device can initiate a first phase of the ALP operation during which a ramping wordline voltage is applied to a set of wordlines including a target wordline associated with the set of memory cells to be programmed.

At operation 730, a set of voltage levels are established. In an implementation, as the ramping wordline voltage is applied to the set of wordlines (in operation 720), the set of pillars are floated in sequence. In an implementation, the pillars refer to the channel regions (e.g., composed of polysilicon) of the access transistors of a vertical string of memory cells. In an implementation, by floating each pillar associated with a respective programming level at different times in operation 730, each pillar is exposed to a different length of the wordline voltage ramp process while in the floating state. In an implementation, as a result each pillar is boosted to a different voltage as a function of the different exposure times associated with the ramping wordline voltage. For example, a first pillar that is floated first in sequence is exposed to a longest relative length of time of the wordline voltage and, as such, is boosted to a highest voltage level, a second pillar that is floated second in sequence is exposed to a next longest relative length of time of the wordline voltage and, as such, is boosted to a next highest voltage level, and so on.

For example, in operation 730, the processing logic can cause a disconnection of a set of pillars associated with the set of memory cells from a voltage supply and ground voltage (i.e., ground), wherein each pillar corresponds to a programming level of a set of programming levels (e.g., L1 to L7 for a TLC memory device). In an implementation, during the first phase of the ALP operation, respective pillars (e.g., vertical conductive traces of the memory array) corresponding to programming levels (e.g., L1 to L6 for a TLC memory device) are floated (e.g., disconnected from both a voltage supply and a ground). In an implementation, the set of pillars corresponding to different programming levels are floated in sequence during the first phase (e.g., a first pillar corresponding to L1 is floated at a first time, a second pillar corresponding to L2 is floated at a second time, and so on).

In an implementation, the pillars are floated by turning a corresponding source-side select transistor (SGD) and a corresponding drain-side select transistor (SGS) off. In an implementation, a pillar can be floated by turning both a select gate source (SGS) off and select gate drain (SGD) off (e.g., a selected SGD is toggled from a high voltage level (e.g., V_{SGD_HIGH}) to approximately 0V to prevent a corresponding bitline from discharging to the corresponding pillar). In an implementation, a bitline corresponding to the first pillar associated with the programming level L1 is toggled from approximately 0V to a high voltage level (e.g., V_{BL_HIGH}) to ensure the pillar remains floating during the remainder of the first phase (e.g., application of the ramping wordline voltage).

In an implementation, once floated, a voltage of each pillar (V_{PILLAR}) can be periodically boosted or increased in accordance with each step or increase of the ramping wordline voltage (e.g., each step of the ramping wordline voltage increases or boosts the pillar voltage for a pillar that is floating). At the end of the first phase, the pillar voltage levels (V_{PILLAR}) are boosted to different voltage levels (e.g., V_{PILLAR} for programming level L1 is boosted to a highest value, V_{PILLAR} for programming level L2 is boosted to a next highest value and so on to V_{PILLAR} for programming level L7 which remains approximately 0V during the first phase).

At operation 740, a programming pulse is applied. For example, the processing logic can cause a programming pulse to be applied to the set of memory cells, wherein the programming pulse programs all programming levels associated with the identified set of memory cells. In an implementation, the programming pulse can be applied to the one or more target wordlines associated with the set of memory cells to be programmed (e.g., the set of memory cells identified in operation 710), wherein the programming pulse programs each of the programming levels together (e.g., programming levels L1 to L7 are programmed using the programming pulses). In an implementation, the boosting of the pillar voltages during a first phase enables the programming of all of the programming levels together using each programming pulse, the memory cells of the respective programming levels can be raised to the corresponding target voltage level in quicker and more efficient manner.

In an implementation, operations 720-740 can be iteratively executed (e.g., phase 1 and phase 2 shown in FIG. 5 are iteratively performed), wherein each execution of operation 740 includes the application of a single programming pulse until each of the programming levels reach the corresponding target voltage level. For example, operations 720-740 can be iteratively performed to enable the execution of pulse 1, pulse 2 . . . pulse N of FIG. 6 until all of the programming levels (e.g., L1 to L7) have been programmed. For each pulse of the set of pulses, a program verify operation can be performed for each programming level to verify that target voltage corresponding to each respective programming level has been reached. In an implementation, the processing logic completes the execution of method 700 in response to verifying (using program verify operations) that all of the programming levels have been programmed (e.g., following the application of set of pulses in accordance with the iterative performance of operations 720-740 of method 700). In an example, the ALP operation can include a set of pulses (e.g., six pulses) to program seven programming levels, results in the application of forty-two program verify operations).

In an implementation, as shown in FIG. 7, operations 720 through 740 can be repeated following the causing of each programming pulse and associated program verify operations until the programming of each programming level is complete.

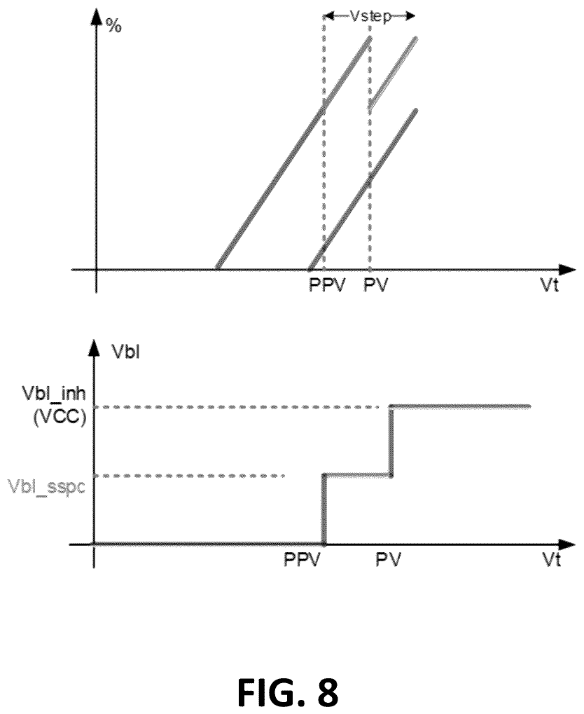

FIG. 8 schematically illustrates the SSPC technique, which involves selectively biasing each bitline with a corresponding bitline voltage in response to the threshold voltage of the associated memory cell reaching a pre-verify threshold voltage level. The bitline bias voltage is a fixed value that is typically greater than ground level (i.e., 0V) and less than the inhibit voltage (e.g., V_{CC}).

In an illustrative example, an SSPC programming operation can apply incrementally increased programming pulses to the selected wordline. After each programming pulse, a program verify operation can performed to verify whether each memory cell of the target set of memory cells has reached the target programming level (PV_{N}) or the pre-program verify level (PPV_{N}). If the threshold voltage of the memory cell has reached the pre-program verify level (PPV_{N}), the bitline connected to that memory cell can be biased by a fixed voltage level (e.g., V_{BL_SSPC}) during the subsequent programming pulses, thus slowing down the change in threshold voltage Vt. In the illustrative example of FIG. 8, the programming state width of each memory cell is a half of the programming voltage increment Vstep.

Other memory cells, whose respective threshold voltages have not yet reached the pre-program verify level (PPVN), can continue to be programmed at their normal pace by the subsequent programming pulse, which can utilize the programming voltage that is increased by a step voltage as compared to the programming voltage of the previous programming pulse. The SSPC programming operation can continue until the memory cell is programmed to the target programming level and the bitline voltage is increased to the inhibit voltage (e.g., Vcc).

Thus, memory cells nearer to their respective target data states are programmed more slowly (e.g., partially enabled for programming) compared to memory cells farther from their respective target data states (e.g., fully enabled for programming) while receiving the same voltage level at their respective control gates.

While in the illustrative example of FIG. 8 a single pre-program verify voltage level is illustrated, in other implementations, two or more pre-program verify voltage levels may be involve, such that each pre-program verify voltage level would correspond to a respective bitline bias voltage level V_{BL_SSPC}.

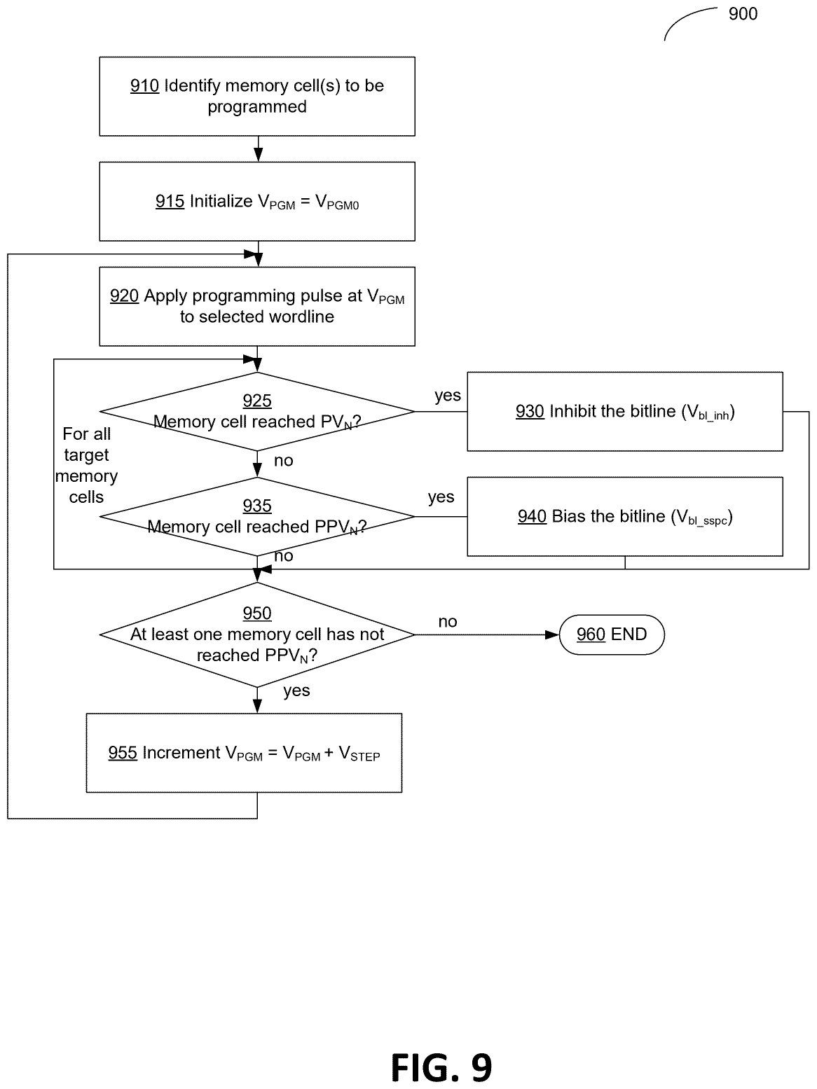

FIG. 9 is a flow diagram of an example method of performing an SSPC memory programming operation, in accordance with implementations of the present disclosure. The method 900 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some implementations, the method 900 is performed by the memory sub-system controller 115 and/or the local media controller 135 of FIGS. 1A-1B. Although shown in a particular sequence or order, unless otherwise specified, the order of the operations can be modified. Thus, the illustrated implementations should be understood only as examples, and the illustrated operations can be performed in a different order, and some operations can be performed in parallel. Additionally, one or more operations can be omitted in various implementations. Thus, not all operations are required in every implementation. The voltage corresponding voltage waveforms are schematically illustrated by FIG. 5.

At operation 910, the controller implementing the method identifies one or more a memory cells to be programmed. In an illustrative example, the program manager 134 implemented by the local media controller 135 of FIGS. 1A-1B can receive, from the memory interface 113 of the memory sub-system controller 115, a request to perform a memory programing operation to program the identified memory cells to a specified logical level. The identified memory cells can be addressable by a target wordline and a set of target bitlines, as described in more detail herein above.

At operation 915, the current programming level (V_{PGM}) is initialized with a predefined value (V_{PGM0}).

At operation 920, a programming pulse at the current programming level (V_{PGM}) is applied to the selected wordline.

At operations 925-935, a program verify operation is performed. The program verify operation involves performing the checks of operations 925 and 935 for each memory cell of the target set of memory cells. Responsive to determining, at operation 925, that a memory cell of the set of target memory cells has reached the program verify level (PV_{N}), the bitline connected to that memory cell is biased, at operation 930, is biased, at operation 940, by the inhibit voltage (e.g., Vcc) for the subsequent programming pulses.

Responsive to determining, at operation 935, that a memory cell of the set of target memory cells has reached the pre-program verify level (PPV_{N}), the bitline connected to that memory cell is biased, at operation 940, by a fixed voltage level (e.g., V_{BL_SSPC}) for the subsequent programming pulses.

Responsive to determining, at operation 950, that at least one memory cell has not yet reached the program verify level (PV_{N}), the current programming level (V_{PGM}) is incremented, at operation 955, by a pre-defined programming voltage increment, and the method loops back to operation 520; otherwise, the method terminates at operation 960.

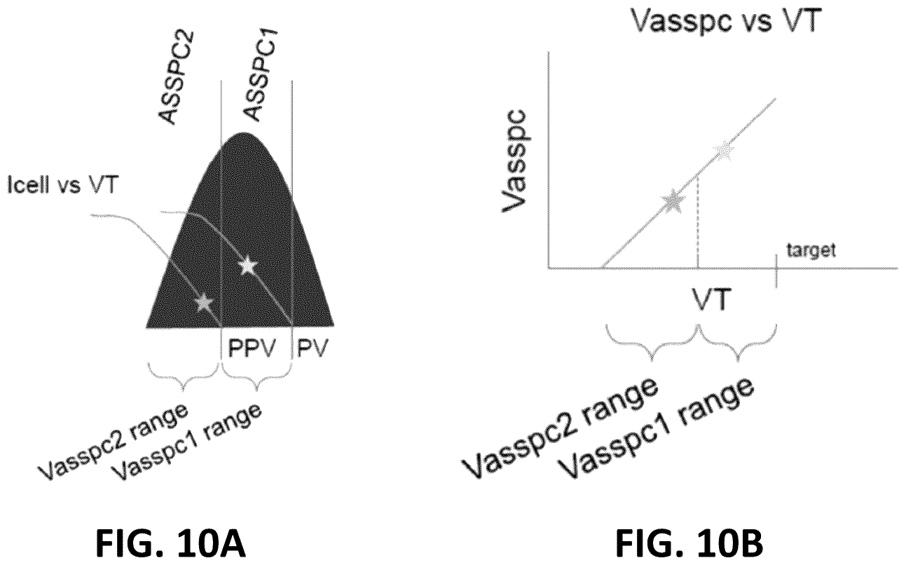

FIGS. 10A-10B schematically illustrates the analog selective slow program convergence (ASSPC) technique, which, instead of using a uniform bitline voltage, uses an analog or continuous voltage applied to the bitline (“analog bitline voltage level” or “continuous bitline voltage level”). Thus, the bitline voltage is biased continuously starting from the time of the threshold voltage of the associated memory cells reaching a corresponding pre-program verify threshold voltage until the bitline voltage reaches the fixed value at the time of threshold voltage of the associated memory cell reaching a program verify threshold voltage.

In particular, FIG. 10A is a graph illustrating a program distribution for a subset of memory cells intended to be programmed to a given program level (i.e., programming state) by an ASSPC programming operation. After the application of a prior program pulse, a certain number of memory cells in the distribution may have reached a threshold voltage that is greater than or equal to the program verify (PV) threshold, and thus do not need to be programmed any further. The processing logic can identify a first subset of memory cells having threshold voltages that are less than the program verify (PV) threshold but greater than the pre-program verify (PPV) threshold. In FIG. 10A, this first subset can include the memory cells in the range labeled “ASSPC1.” The processing logic can identify a second subset of memory cells having threshold voltages that are less than the pre-program verify (PPV) threshold. In FIG. 10A, this second subset can include the memory cells in the range labeled “ASSPC2.” In other implementations, there can be some other number of subsets and/or the subsets of memory cells can be identified using different or additional criteria. The ICELL VS threshold voltage (VT) curves represent the cell current being drawn by the string in response to a gate bias (e.g., PPV or PV). For example, if a cell had a VT position at the PV threshold, the ICELL, would be low. As this cell VT moves lower, the corresponding cell current would increase with some relation to the VT.

FIG. 10B is a graph illustrating the bitline bias voltages applied to different memory cells during analog program converge in accordance with some implementations of the present disclosure. In some implementations, a voltage supply in the memory sub-system 110 may be configured to provide a range of bitline bias voltages (Vasspc) for memory cells having threshold voltages (VT) that fall within the Vasspc2 range. In order to increase the effective bitline bias voltages for those memory cells having threshold voltages (VT) that fall within the Vasspc1 range, program convergence management component 150 boost the voltage potential in the corresponding pillars, as is described in more detail below.

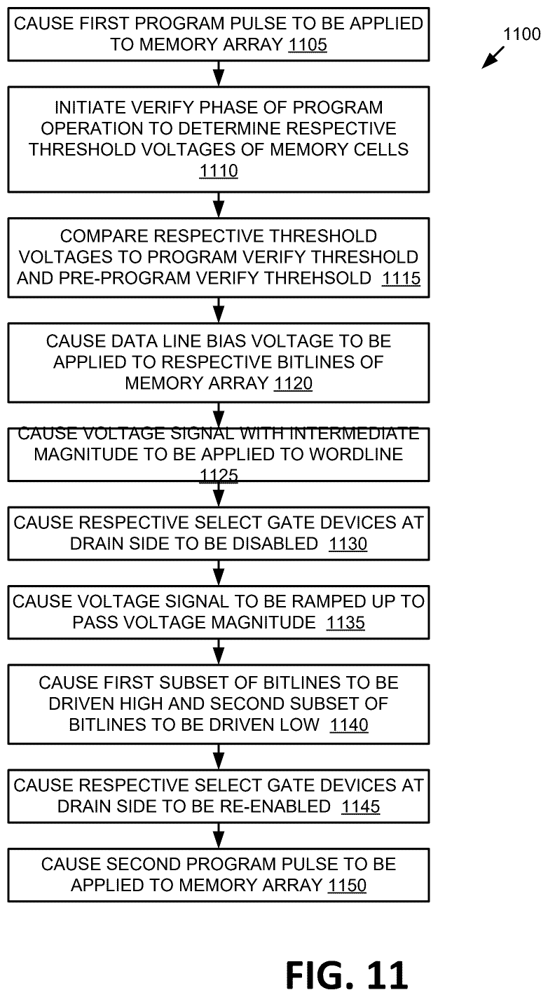

FIG. 11 is a flow diagram of an example method of performing an ASSPC memory programming operation, in accordance with implementations of the present disclosure. The method 900 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some implementations, the method 1100 is performed by the memory sub-system controller 115 and/or the local media controller 135 of FIGS. 1A-1B. Although shown in a particular sequence or order, unless otherwise specified, the order of the operations can be modified. Thus, the illustrated implementations should be understood only as examples, and the illustrated operations can be performed in a different order, and some operations can be performed in parallel. Additionally, one or more operations can be omitted in various implementations. Thus, not all operations are required in every implementation.

At operation 1105, a program pulse is applied. For example, the processing logic (e.g., program convergence management component 150) can cause a first program pulse, of a plurality of program pulses associated with a program operation, to be applied to a memory array 104 of a memory device, such as memory device 130. In some implementations, the first program pulse is applied to a selected wordline of memory array 104 associated with one or more memory cells to be programmed to certain program levels (e.g., states).

At operation 1110, a verify phase of the program operation is initiated. For example, the processing logic can initiate a verify phase of the program operation to determine respective threshold voltages of the plurality of memory cells after application of the first program pulse. In some implementations, after each program pulse is applied, a program verify pulse can be applied to determine the respective threshold voltages of each memory cell associated with the selected wordline.

At operation 1115, a comparison is performed. For example, the processing logic can compare the respective threshold voltages to a program verify (PV) threshold level and a pre-program verify (PPV) threshold level. As illustrated in FIG. 10A, the processing logic can identify a first subset of memory cells in the range labeled “ASSPC1” having threshold voltages that are less than the program verify (PV) threshold but greater than the pre-program verify (PPV) threshold. The processing logic can further identify a second subset of memory cells in the range labeled “ASSPC2” having threshold voltages that are less than the pre-program verify (PPV) threshold.

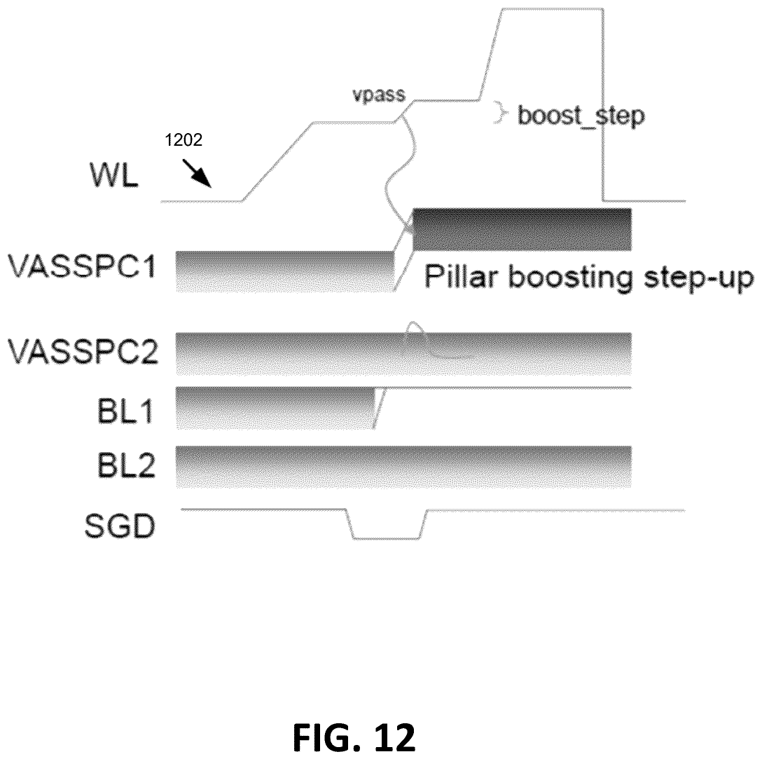

At operation 1120, a bitline bias voltage is applied. For example, the processing logic can cause a bitline bias voltage to be applied to a plurality of respective bitlines corresponding to the plurality of memory cells. This bitline bias voltage (V_{ASSPC}) can be any of a number of voltage magnitudes that are able to be generated by a voltage source in the memory sub-system 110. In some implementations, the bitline bias voltage applied to the bitlines corresponding to the first subset of memory cells (i.e., BL1 and represented by V_{ASSPC1}) and the bitline bias voltage applied to the bitlines corresponding to the second subset of memory cells (i.e., BL2 and represented by V_{ASSPC2}) are initially of the same magnitude, as shown in FIG. 12. FIG. 12 is a diagram illustrating the various signals applied during multi-step analog program convergence in accordance with some implementations of the present disclosure. It should be noted that in FIG. 12, the signals BL1 and BL2, and the corresponding effective bitline bias voltage levels V_{ASSPC1} and V_{ASSPC2}, are illustrated as gradient bars to indicate that the actual bitline bias voltage corresponding to each individual memory cell can be any voltage magnitude within a certain range, and that the bitline bias voltages applied to different memory cells can vary according to the analog nature of the algorithm (e.g., based on the different cell currents (ICELL)). In some implementations, the processing logic performs a current integration of ICELL onto a capacitor. This capacitor can be initially precharged to some level and subsequently discharged with a current equal to ICELL for a specific time interval. Afterwards, the discharged voltage on the capacitor is proportional to ICELL. Thus, for a cell with low ICELL, this capacitor voltage is higher, while a cell with high ICELL has a lower capacitor voltage. The voltage is then transferred to the gate of a source-follower driver which drives this bias onto the bitline during the program pulse phase, where the bias is inversely proportional to ICELL.

Referring again to FIG. 11, at operation 1125, a voltage signal is applied to a wordline. For example, the processing logic can cause a voltage signal to be applied to a wordline associated with the plurality of memory cells (i.e., the selected wordline), the voltage signal having an intermediate magnitude. As shown in FIG. 12, the voltage signal 602 can be ramped up from a low voltage (e.g., 0V) to the intermediate voltage, which can be represented as the pass voltage (V_{PASS}) minus a boost step amount (boost_step). The boost step amount is a configurable amount that can vary depending on the implementation.

At operation 1130, a select gate device is disabled. For example, the processing logic can cause respective select gate devices (e.g., one or more of select gates 212₀ to 212_{M}) at a drain side of the one or more pillars to be disabled. The select gate devices can be disabled via control signal SGD (i.e., by driving the SGD signal low for a period of time). Disabling the select gate devices disconnects the pillars from the corresponding bitlines (e.g., bitlines) causing the pillars to float.

At operation 1135, the voltage signal is increased. For example, the processing logic can cause the voltage signal 602 applied to the selected wordline to be ramped up to a pass voltage magnitude (V_{PASS}). As described above, the pass voltage magnitude is greater than the intermediate magnitude by the boost step amount (boost_step). The increased magnitude of voltage signal 602 will boost the voltage potential in each of the pillars in the memory array, including those corresponding to memory cells in both the V_{ASSPC1} and V_{ASSPC2} ranges. In FIG. 12, this is illustrated by effective bitline bias voltage V_{ASSPC1} being boosted a higher magnitude (i.e., the “Pillar boosting step-up”). It should be noted that the effective bitline bias voltage V_{ASSPC2} is also boosted to a higher magnitude, although only temporarily and will be brought back down, as described in more detail below.

At operation 1140, bitlines are biased. For example, the processing logic can cause a first subset of the plurality of bitlines associated with the first subset of the plurality of memory cells (i.e., the cells in the Vasspc1 range) to be driven with a high voltage. This is illustrated in FIG. 12 by the signal BL1 being driven to a high state (i.e., greater than the bitline bias voltage magnitude at which it was previously). In addition, the processing logic can cause a second subset of the plurality of bitlines associated with the second subset of the plurality of memory cells (i.e., the cells in the Vasspc2 range) to be driven with the original bitline bias voltage. This is illustrated in FIG. 12 by the signal BL2 remaining at the same level.

At operation 1145, a select gate device is enabled. For example, the processing logic can cause the respective select gate devices to be re-enabled. The select gate devices can be enabled via control signal SGD (i.e., by driving the SGD signal high again). Once the select gate devices are reenabled, the effective bitline bias voltage (V_{ASSPC2}) for the second subset of memory cells is driven back down to the original magnitude because the signal BL2 remains unchanged. Since the signal BL1 is driven high, however, the effective bitline bias voltage (V_{ASSPC2}) for the first subset of memory cells remains at the boosted potential level. When the select gate is re-enabled, BL2 is re-driven into the pillar to restore the pillar potential represented by V_{ASSPC2} back to an originally intended target after being boosted up. The signal BL1 is driven high in order to cut off the pillar intended for the V_{ASSPC2} level. Thus, when SGD is re-enabled, the pillar remains at the boosted potential. This requires careful control of the boost_step, SGD bias, BL1, and BL2 levels to ensure that the boosted potential for V_{ASSPC1} can be retain while being able to drive V_{ASSPC1} at the same time. Accordingly, a higher range of effective bitline bias voltages are available for those memory cells having threshold voltages (VT) that fall within the Vasspc1 range, as illustrated in FIG. 10B.

At operation 1150, a program pulse is applied. For example, the processing logic can cause the voltage signal 1202 applied to the wordline to be ramped up to a program voltage magnitude corresponding to the second program pulse. When the second program pulse is applied to a selected wordline, the level of partial program enablement can be controlled by the differences in the bitline bias voltages applied to different memory cells, including the higher effective bitline bias voltages applied to those memory cells in the V_{ASSPC1} range. As a result, memory cells closer to their target threshold voltage can receive a higher data line bias voltage (e.g., a lower level of partial enablement) and thus will be programmed “slower” and memory cells farther from their target threshold voltage can receive a lower data line bias voltage (e.g., higher level of partial enablement) and thus will be programmed “faster.”

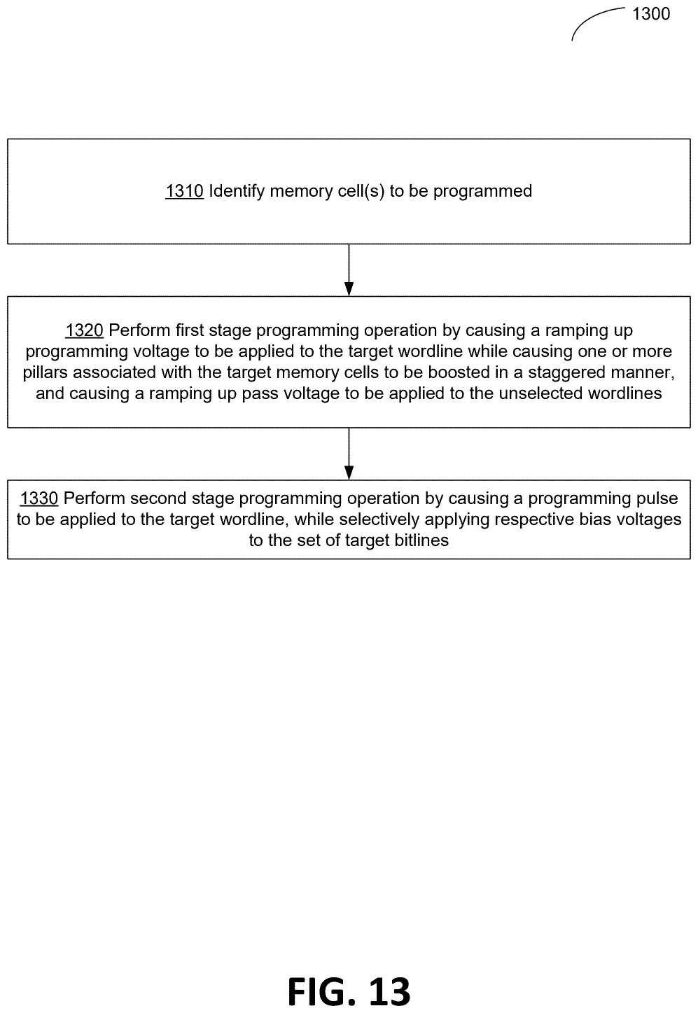

FIG. 13 is a flow diagram of an example method of performing a two-stage memory programming operation, in accordance with implementations of the present disclosure. The method 800 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some implementations, the method 1300 is performed by the memory sub-system controller 115 and/or the local media controller 135 of FIGS. 1A-1B. Although shown in a particular sequence or order, unless otherwise specified, the order of the operations can be modified. Thus, the illustrated implementations should be understood only as examples, and the illustrated operations can be performed in a different order, and some operations can be performed in parallel. Additionally, one or more operations can be omitted in various implementations. Thus, not all operations are required in every implementation.

At operation 1310, the controller implementing the method identifies one or more a memory cells to be programmed. In an illustrative example, the program manager 134 implemented by the local media controller 135 of FIGS. 1A-1B can receive, from the memory interface 113 of the memory sub-system controller 115, a request to perform a memory access operation on a specified memory device. In some implementations, the memory access operation involves a programming operation to program the identified memory cells to a specified logical level. The identified memory cells can be addressable by a target wordline and a set of target bitlines, as described in more detail herein above.

At operation 1320, the controller performs the first stage of the memory programming operation, which can involve causing a ramping up programming voltage to be applied to the target wordline while causing one or more pillars associated with the target memory cells to be boosted in a staggered manner, and causing a ramping up pass voltage to be applied to the unselected wordlines. In some implementations, the first stage of the memory programming operation may further include performing a program verify operation with respect to the target set of memory cells, in order to classifying the target set of memory cells into a pre-defined number of categories based on positions of threshold voltage levels of respective memory cells with respect to corresponding desired threshold voltage levels. Accordingly, the respective bias voltages applied to the set of target bitlines can be determined based on a program verify operation performed with respect to the target set of memory cells, as described in more detail herein above.

At operation 1330, the controller performs the second stage of the memory programming operation, which can involve causing a programming pulse to be applied to the target wordline, while selectively applying respective bias voltages to the set of target bitlines.

In some implementations, the second stage of the memory programming operation may employ the SPCC technique. Accordingly, the second stage of the memory programming operation can further include causing an initial bitline voltage to be applied to a subset of the target set of memory cells having a threshold voltage in the range between a pre-program verify voltage and a program verify voltage, followed by causing an adjusted bitline voltage to be applied to the subset of the target set of memory cells.

In some implementations, the second stage of the memory programming operation may employ the ASPCC technique. Accordingly, the second stage of the memory programming operation can further include identifying a first subset of the target set of memory cells and a second subset of the target set of memory cells based on respective threshold voltages after application of the programming pulse, followed by boosting a voltage potential in one or more pillars corresponding to the first subset of the plurality of memory cells prior to application of a subsequent program pulse.

The above-described examples and methods can be applied to memory cells that are capable of storing one or more data bits, including SLC, MLC, TLC, or QLC.

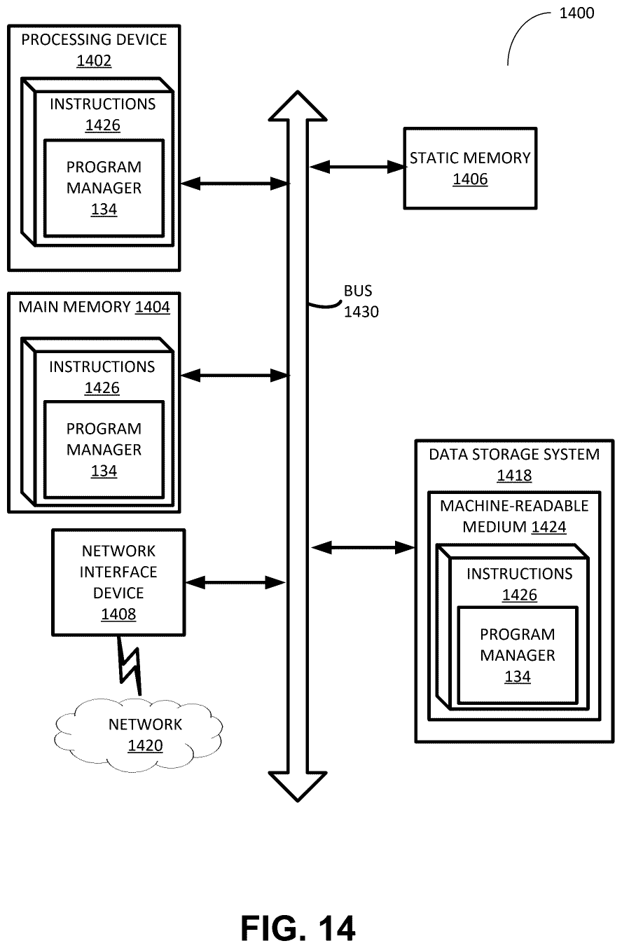

FIG. 14 illustrates an example machine of a computer system 1400 within which a set of instructions, for causing the machine to perform any one or more of the methodologies discussed herein, can be executed. In some implementations, the computer system 1400 can correspond to a host system (e.g., the host system 120 of FIGS. 1A-1B) that includes, is coupled to, or utilizes a memory sub-system (e.g., the memory sub-system 110 of FIGS. 1A-1B) or can be used to perform the operations of a controller (e.g., to execute an operating system to perform operations corresponding to program manager 134 of FIGS. 1A-1B). In alternative implementations, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 1400 includes a processing device 1402, a main memory 1404 (e.g., read-only memory (ROM), flash memory, dynamic random access memory (DRAM) such as synchronous DRAM (SDRAM) or Rambus DRAM (RDRAM), etc.), a static memory 1406 (e.g., flash memory, static random access memory (SRAM), etc.), and a data storage system 1419, which communicate with each other via a bus 1430.

Processing device 1402 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 1402 can also be one or more special-purpose processing devices such as an application specific integrated circuit (ASIC), a field programmable gate array (FPGA), a digital signal processor (DSP), network processor, or the like. The processing device 1402 is configured to execute instructions 1426 for performing the operations and steps discussed herein. The computer system 1400 can further include a network interface device 1409 to communicate over the network 1420.

The data storage system 1419 can include a machine-readable storage medium 1 144 (also known as a computer-readable medium, such as a non-transitory computer-readable medium) on which is stored one or more sets of instructions 1426 or software embodying any one or more of the methodologies or functions described herein. The instructions 1426 can also reside, completely or at least partially, within the main memory 1404 and/or within the processing device 1402 during execution thereof by the computer system 1400, the main memory 1404 and the processing device 1402 also constituting machine-readable storage media. The machine-readable storage medium 1424, data storage system 1419, and/or main memory 1404 can correspond to the memory sub-system 114 of FIGS. 1A-1B.

In some implementations, the instructions 1426 include instructions to implement functionality corresponding to program manager 134 of FIGS. 1A-1B (e.g., instructions implementing methods 700, 900, 1100, and/or 1300).

While the machine-readable storage medium 1424 is shown in an example implementation to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some implementations, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, implementations of the disclosure have been described with reference to specific example implementations thereof. It will be evident that various modifications can be made thereto without departing from the broader spirit and scope of implementations of the disclosure as set forth in the following claims. The specification and drawings are, accordingly, to be regarded in an illustrative sense rather than a restrictive sense.

What is claimed is:

1. A system, comprising:
a memory array comprising a plurality of memory cells; and
a controller coupled to the memory array, the controller to perform operations comprising:
receiving a request to perform a memory programming operation with respect to a target set of memory cells electrically coupled to a target wordline and a set of target bitlines;
performing a first stage of the memory programming operation by causing a ramping up programming voltage to be applied to the target wordline while causing one or more pillars associated with the target memory cells to be boosted in a staggered manner; and
performing a second stage of the memory programming operation by causing a programming pulse to be applied to the target wordline, while selectively applying respective bias voltages to the set of target bitlines.

2. The system of claim 1, wherein performing the first stage of the memory programming operation further comprises:
causing a ramping up pass voltage to be applied to unselected wordlines.

3. The system of claim 1, wherein performing the first stage of the memory programming operation further comprises:
causing a program verify operation to be performed with respect to the target set of memory cells.

4. The system of claim 1, wherein performing the first stage of the memory programming operation further comprises:
classifying, by performing a program verify operation, the target set of memory cells into a pre-defined number of categories based on positions of threshold voltage levels of respective memory cells with respect to corresponding desired threshold voltage levels.

5. The system of claim 1, wherein the respective bias voltages applied to the set of target bitlines are determined based on a program verify operation performed with respect to the target set of memory cells.

6. The system of claim 1, wherein performing the second stage of the memory programming operation further comprises:
causing an initial bitline voltage to be applied to a subset of the target set of memory cells having a threshold voltage in a range between a pre-program verify voltage and a program verify voltage; and
causing an adjusted bitline voltage to be applied to the subset of the target set of memory cells.

7. The system of claim 1, wherein performing the second stage of the memory programming operation further comprises:
identifying a first subset of the target set of memory cells and a second subset of the target set of memory cells based on respective threshold voltages after application of the programming pulse; and
boosting a voltage potential in one or more pillars corresponding to the first subset of the target set of memory cells prior to application of a subsequent program pulse.

8. A computer-readable non-transitory storage medium comprising executable instructions that, when executed by a controller managing a memory array comprising a plurality of memory cells, cause the controller to perform operations, comprising:
receiving a request to perform a memory programming operation with respect to a target set of memory cells electrically coupled to a target wordline and a set of target bitlines;
performing a first stage of the memory programming operation by causing a ramping up programming voltage to be applied to the target wordline while causing one or more pillars associated with the target memory cells to be boosted in a staggered manner; and
performing a second stage of the memory programming operation by causing a programming pulse to be applied to the target wordline, while selectively applying respective bias voltages to the set of target bitlines.

9. The computer-readable non-transitory storage medium of claim 8, wherein performing the first stage of the memory programming operation further comprises:
causing a ramping up pass voltage to be applied to unselected wordlines.

10. The computer-readable non-transitory storage medium of claim 8, wherein performing the first stage of the memory programming operation further comprises:
causing a program verify operation to be performed with respect to the target set of memory cells.

11. The computer-readable non-transitory storage medium of claim 8, wherein performing the first stage of the memory programming operation further comprises:
classifying, by performing a program verify operation, the target set of memory cells into a pre-defined number of categories based on positions of threshold voltage levels of respective memory cells with respect to corresponding desired threshold voltage levels.

12. The computer-readable non-transitory storage medium of claim 8, wherein the respective bias voltages applied to the set of target bitlines are determined based on a program verify operation performed with respect to the target set of memory cells.

13. The computer-readable non-transitory storage medium of claim 8, wherein performing the second stage of the memory programming operation further comprises:
causing an initial bitline voltage to be applied to a subset of the target set of memory cells having a threshold voltage in a range between a pre-program verify voltage and a program verify voltage; and
causing an adjusted bitline voltage to be applied to the subset of the target set of memory cells.

14. The computer-readable non-transitory storage medium of claim 8, wherein performing the second stage of the memory programming operation further comprises:
identifying a first subset of the target set of memory cells and a second subset of the target set of memory cells based on respective threshold voltages after application of the programming pulse; and
boosting a voltage potential in one or more pillars corresponding to the first subset of the target set of memory cells prior to application of a subsequent program pulse.

15. A method, comprising:
receiving, by a processing device, a request to perform a memory programming operation with respect to a target set of memory cells electrically coupled to a target wordline and a set of target bitlines;
performing a first stage of the memory programming operation by causing a ramping up programming voltage to be applied to the target wordline while causing one or more pillars associated with the target memory cells to be boosted in a staggered manner; and
performing a second stage of the memory programming operation by causing a programming pulse to be applied to the target wordline, while selectively applying respective bias voltages to the set of target bitlines.

16. The method of claim 15, wherein performing the first stage of the memory programming operation further comprises:
causing a ramping up pass voltage to be applied to unselected wordlines.

17. The method of claim 15, wherein performing the first stage of the memory programming operation further comprises:
causing a program verify operation to be performed with respect to the target set of memory cells.

18. The method of claim 15, wherein performing the first stage of the memory programming operation further comprises:
classifying, by performing a program verify operation, the target set of memory cells into a pre-defined number of categories based on positions of threshold voltage levels of respective memory cells with respect to corresponding desired threshold voltage levels.

19. The method of claim 15, wherein performing the second stage of the memory programming operation further comprises:
causing an initial bitline voltage to be applied to a subset of the target set of memory cells having a threshold voltage in a range between a pre-program verify voltage and a program verify voltage; and
causing an adjusted bitline voltage to be applied to the subset of the target set of memory cells.

20. The method of claim 15, wherein performing the second stage of the memory programming operation further comprises:
identifying a first subset of the target set of memory cells and a second subset of the target set of memory cells based on respective threshold voltages after application of the programming pulse; and
boosting a voltage potential in one or more pillars corresponding to the first subset of the target set of memory cells prior to application of a subsequent program pulse.
